(19) United States
(12) Patent Application Publication
(10) Pub. No.: US 2024/0078364 A1
(43) Pub. Date: Mar. 7, 2024

(54) TECHNOLOGIES FOR PRODUCING SAMPLING AND ANALYSIS PLANS FOR EVALUATING AIRBORNE CHEMICAL HAZARDS

(71) Applicant: Battelle Memorial Institute, Columbus, OH (US)

(72) Inventors: Robert A. Lordo, Columbus, OH (US); Paul S. Pirkle, III, Larkspur, CO (US)

(21) Appl. No.: 18/242,678

(22) Filed: Sep. 6, 2023

Related U.S. Application Data
(60) Provisional application No. 63/404,386, filed on Sep. 7, 2022.

(51) Int. Cl. G06F 30/28

(52) U.S. Cl. CPC G06F 30/28

(57) ABSTRACT

Technologies for producing sampling and analysis plans for evaluating airborne chemical hazards are disclosed. These technologies obtain scenario data indicative of emission of an airborne chemical at a site with a human population; simulate, as a function of the scenario data, emission of the chemical at the site and transport and dispersion of a plume of the chemical across the site in space and time; assess an extent to which concentrations of the chemical in the airborne plume encounter areas containing people, as a function of time and projected human activity and movement across the site; determine, based on the simulation and assessment, recommended sampler device locations to obtain a target quality and target quantity of samples of the chemical for use in a sampling and analysis plan to determine an effect of the chemical on the human population at the site; and present the recommended sampler device locations.

### CROSS-REFERENCE TO RELATED APPLICATIONS

This application claims priority to and the benefit of U.S. Provisional Patent Application No. 63/404,386, filed Sep. 7, 2023, the entire disclosure of which is incorporated herein by reference.

### STATEMENT REGARDING FEDERALLY SPONSORED RESEARCH OR DEVELOPMENT

This invention was made with government support under FA8650-19-2-6985 awarded by the United States Air Force. The government has certain rights in the invention.

### BACKGROUND

Personnel operating in areas with airborne environmental hazards present, such as overseas U.S. military bases that utilize burn pits, may be at heightened risk of developing acute or chronic health problems resulting from exposure to high levels of airborne contaminants. As such, risk assessment personnel (e.g., bioenvironmental engineering personnel deployed at the military base) may be tasked with assessing exposure pathways and determining the associated human health risks from select hazards of concern, such as airborne chemical hazards that military personnel may be exposed to during the course of a military deployment. Exposure data obtained through sampling and analysis of environmental media within the area of interest may be used to characterize and evaluate the exposure risks. However, due to the complexity of activity and movement patterns of people at the site, varying weather phenomena, and general site layout, it may be difficult or impossible for a human to determine (on his own) the locations and timing for the optimal placement of available air sampler devices at the site that will generate the quality and quantity of data needed for a risk assessor to make accurate conclusions on exposure risk among the target population with a certain degree of statistical confidence.

### SUMMARY

According to one aspect, a compute device for facilitating an analysis of airborne chemical hazards may comprise circuitry configured to obtain scenario data indicative of emission of an airborne chemical at a site with a human population. The scenario data may include meteorological data for the site and a location of an emission source for the airborne chemical. The circuitry may be further configured to simulate, as a function of the scenario data, emission of the chemical at the site and transport and dispersion of a plume of the chemical across the site in space and time. The circuitry may be further configured to assess an extent to which concentrations of the chemical in the airborne plume encounter areas containing people, as a function of time of day and projected human activity and movement across the site. The circuitry may be further configured to determine, based on the simulation and assessment, recommended sampler device locations to obtain a target quality and target quantity of samples of the chemical for use in a sampling and analysis plan to determine an effect of the chemical on the human population at the site. The circuitry may be further configured to present the recommended sampler device locations.

In some embodiments, the circuitry may be configured to obtain scenario data by obtaining sector data indicative of locations and shapes of sectors within the site, including population data indicative of the human population in each sector and activity data indicative of a level of human activity per hour in each sector. Obtaining the sector data may comprise obtaining data indicative of at least one sector in which sampler device placement is prohibited.

In some embodiments, the circuitry may be configured to obtain scenario data by obtaining emission source data indicative of properties of the emission source, including the size of the emission source and temperature over time for the emission source.

In some embodiments, the circuitry be configured to obtain scenario data by obtaining data indicative of a location of the site and a perimeter of the site, data indicative of perimeters of one or more buildings at the site, data indicative of an identity and one or more properties of the chemical, data indicative of a profile of the chemical, data indicative of a sector of heightened interest to be prioritized for sampler device placement, data indicative of air sampling parameters for the chemical, data indicative of a predefined sampler device location that cannot be modified, data indicative of a field blank or duplicate samples, and/or data indicative of an analytical method, equipment, sample media, sampling duration, sample rate, sampling volume, and a quantity of sampler devices.

In some embodiments, the circuitry may be configured to obtain the meteorological data by obtaining data indicative of historical weather data for the site for multiple years and data indicative of hourly air temperature, wind speed, wind direction, and atmospheric stability measures.

In some embodiments, the circuitry may be further configured to obtain simulation data indicative of parameters under which to simulate emission of the chemical at the site. The simulation data may include data indicative of start and end dates for a sampling window, data indicative of a number of steps per hour, data indicative of a size of each cell in a grid to be overlaid onto the site, data indicative of a minimum distance between sampler devices, and data indicative of a sampling duration.

In some embodiments, the circuitry may be further configured to obtain data indicative of user defined candidate sampler device locations and to display differences between the recommended sampler devices locations and the candidate sampler device locations.

In some embodiments, the circuitry may be further configured to present a recommended date and time at which to begin sample collection and/or an optimality score indicative of a divergence from recommended sampler device locations due to sampler device placement restrictions.

In some embodiments, the circuitry may be further configured to display plume, activity, population, or exposure risk potential over time.

In some embodiments, the circuitry may be configured to present the recommended sampler device locations by producing a sampling and analysis plan document.

According to another aspect, a method may comprise obtaining, by a compute device, scenario data indicative of emission of an airborne chemical at a site with a human population. The scenario data may include meteorological data for the site and a location of an emission source for the airborne chemical. The method may further comprise simulating, by the compute device and as a function of the scenario data, emission of the chemical at the site and transport and dispersion of a plume of the chemical across the site in space and time. The method may further comprise assessing an extent to which concentrations of the chemical in the airborne plume encounter areas containing people, as a function of time of day and projected human activity and movement across the site. The method may further comprise determining, by the compute device and based on the simulation, recommended sampler device locations to obtain a target quality and target quantity of samples of the chemical for use in a sampling and analysis plan to determine an effect of the chemical on the human population at the site. The method may further comprise presenting, by the compute device, the recommended sampler device locations.

In some embodiments, obtaining scenario data may comprise obtaining sector data indicative of locations and shapes of sectors within the site, including population data indicative of the human population in each sector and activity data indicative of a level of human activity per hour in each sector. Obtaining the sector data may comprise obtaining data indicative of at least one sector in which sampler device placement is prohibited.

In some embodiments, obtaining the scenario data may comprise obtaining emission source data indicative of properties of the emission source, including the size of the emission source and temperature over time for the emission source.

In some embodiments, obtaining the scenario data may comprise obtaining data indicative of a location of the site and a perimeter of the site, data indicative of perimeters of one or more buildings at the site, data indicative of an identity and one or more properties of the chemical, data indicative of a profile of the chemical, data indicative of a sector of heightened interest to be prioritized for sampler device placement, data indicative of air sampling parameters for the chemical, data indicative of a predefined sampler device location that cannot be modified, data indicative of a field blank or duplicate samples, and/or data indicative of an analytical method, equipment, sample media, sampling duration, sample rate, sampling volume, and a quantity of sampler devices.

In some embodiments, obtaining the meteorological data may comprise obtaining data indicative of historical weather data for the site for multiple years and data indicative of hourly air temperature, wind speed, wind direction, and atmospheric stability measures.

In some embodiments, the method may further comprise obtaining, by the compute device, simulation data indicative of parameters under which to simulate emission of the chemical at the site. The simulation data may include data indicative of start and end dates for a sampling window, data indicative of a number of steps per hour, data indicative of a size of each cell in a grid to be overlaid onto the site, data indicative of a minimum distance between sampler devices, and data indicative of a sampling duration.

In some embodiments, the method may further comprise obtaining, by the compute device, data indicative of user defined candidate sampler device locations and displaying, by the compute device, differences between the recommended sampler devices locations and the candidate sampler device locations.

In some embodiments, the method may further comprise presenting, by the compute device, a recommended date and time at which to begin sample collection and/or an optimality score indicative of a divergence from recommended sampler device locations due to sampler device placement restrictions.

In some embodiments, the method may further comprise displaying, by the compute device, plume, activity, population, or exposure risk potential over time.

In some embodiments, presenting the recommended sampler device locations may comprise producing a sampling and analysis plan document.

According to yet another aspect, one or more machine-readable storage media may comprise a plurality of instructions stored thereon that, in response to being executed, cause a compute device to obtain scenario data indicative of emission of an airborne chemical at a site with a human population. The scenario data may include meteorological data for the site and a location of an emission source for the airborne chemical. The plurality of instructions, when executed, may further cause the compute device to simulate, as a function of the scenario data, emission of the chemical at the site and transport and dispersion of a plume of the chemical across the site in space and time. The plurality of instructions, when executed, may further cause the compute device to assessing an extent to which concentrations of the chemical in the airborne plume encounter areas containing people, as a function of time of day and projected human activity and movement across the site. The plurality of instructions, when executed, may further cause the compute device to determine, based on the simulation, recommended sampler device locations to obtain a target quality and target quantity of samples of the chemical for use in a sampling and analysis plan to determine an effect of the chemical on the human population at the site. The plurality of instructions, when executed, may further cause the compute device to present the recommended sampler device locations.

In some embodiments, the plurality of instructions, when executed, may cause the compute device to obtain scenario data by obtaining sector data indicative of locations and shapes of sectors within the site, including population data indicative of the human population in each sector and activity data indicative of a level of human activity per hour in each sector. Obtaining the sector data may comprise obtaining data indicative of at least one sector in which sampler device placement is prohibited.

In some embodiments, the plurality of instructions, when executed, may cause the compute device to obtain scenario data by obtaining emission source data indicative of properties of the emission source, including the size of the emission source and temperature over time for the emission source.

In some embodiments, the plurality of instructions, when executed, may cause the compute device to obtain scenario data by obtaining data indicative of a location of the site and a perimeter of the site, data indicative of perimeters of one or more buildings at the site, data indicative of an identity and one or more properties of the chemical, data indicative of a profile of the chemical, data indicative of a sector of heightened interest to be prioritized for sampler device placement, data indicative of air sampling parameters for the chemical, data indicative of a predefined sampler device location that cannot be modified, data indicative of a field blank or duplicate samples, and/or data indicative of an analytical method, equipment, sample media, sampling duration, sample rate, sampling volume, and a quantity of sampler devices.

In some embodiments, the plurality of instructions, when executed, may further cause the compute device to obtain the meteorological data by obtaining data indicative of historical weather data for the site for multiple years and data indicative of hourly air temperature, wind speed, wind direction, and atmospheric stability measures.

In some embodiments, the plurality of instructions, when executed, may further cause the compute device to obtain simulation data indicative of parameters under which to simulate emission of the chemical at the site. The simulation data may include data indicative of start and end dates for a sampling window, data indicative of a number of steps per hour, data indicative of a size of each cell in a grid to be overlaid onto the site, data indicative of a minimum distance between sampler devices, and data indicative of a sampling duration.

In some embodiments, the plurality of instructions, when executed, may further cause the compute device to obtain data indicative of user defined candidate sampler device locations and to display differences between the recommended sampler devices locations and the candidate sampler device locations.

In some embodiments, the plurality of instructions, when executed, may further cause the compute device to present a recommended date and time at which to begin sample collection and/or an optimality score indicative of a divergence from recommended sampler device locations due to sampler device placement restrictions.

In some embodiments, the plurality of instructions, when executed, may further cause the compute device to display plume, activity, population, or exposure risk potential over time.

In some embodiments, the plurality of instructions, when executed, may cause the compute device to present the recommended sampler device locations by producing a sampling and analysis plan document.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements. The detailed description particularly refers to the accompanying figures in which:

FIG. 1 is a diagram of an embodiment of a site at which a chemical is emitted from an emission source in the presence of a human population;

FIG. 2 is a simplified block diagram an analysis compute device for producing a sampling and analysis plan for use in analyzing exposure risks associated with the chemical emitted at the site of FIG. 1;

FIGS. 3-6 are simplified block diagrams of at least one embodiment of a method for producing a sampling and analysis plan that may be performed by the analysis compute device of FIG. 2;

FIGS. 7-38 are diagrams of user interfaces that may be presented by the analysis compute device of FIG. 2;

FIGS. 39-41 are diagrams of sections of a sampling and analysis plan document that may be produced by the analysis compute device of FIG. 2; and

FIGS. 42A and 42B are a chart of types of information that may be included in the sampling and analysis plan document of FIGS. 39-41.

### DETAILED DESCRIPTION OF THE DRAWINGS

While the concepts of the present disclosure are susceptible to various modifications and alternative forms, specific embodiments thereof have been shown by way of example in the drawings and will be described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment,” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

The disclosed embodiments may be implemented, in some cases, in hardware, firmware, software, or any combination thereof. The disclosed embodiments may also be implemented as instructions carried by or stored on a transitory or non-transitory machine-readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features.

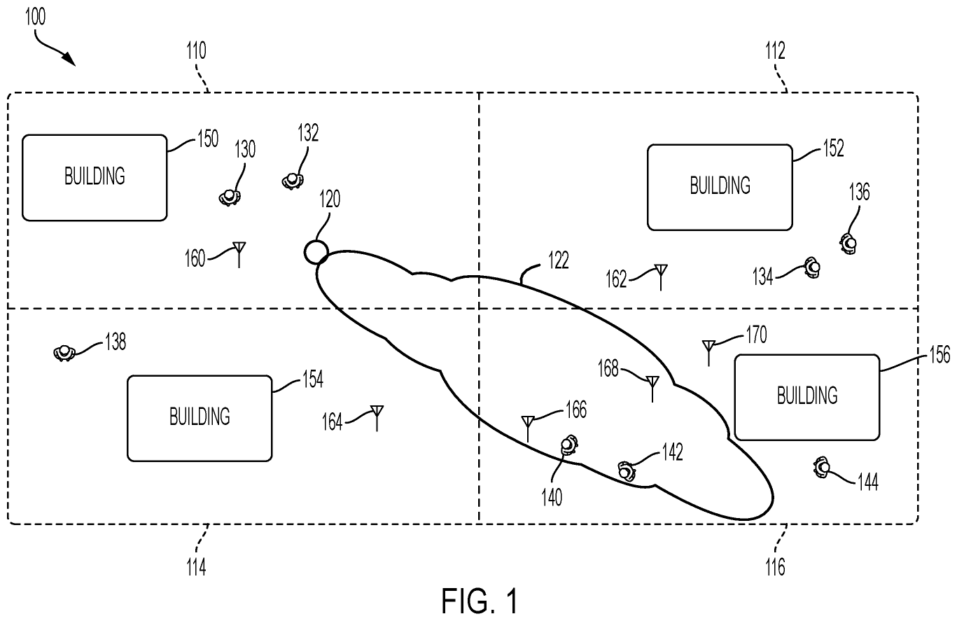

Referring now to FIG. 1, a site 100, which is organized into multiple subsections or segments 110, 112, 114, 116, includes an emission source 120 for a chemical that may present a hazard to a set of people 130, 132, 134, 136, 138, 140, 142, 144 present at the site 100. In the illustrative embodiment, the site 100 is an air base at which military personnel (e.g., the people 130, 132, 134, 136, 138, 140, 142, 144) are deployed to carry out operations. In other embodiments, the site 100 may be any other geographic area in which a contaminant is emitted in the presence of a human population. The emission source 120, which may be embodied as any source that emits one or more potentially hazardous chemicals into the air, is a burn pit that emits benzo(a)pyrene (e.g., the chemical) in the air within the illustrative embodiment. It should be understood that the emission source 120 may have a different cause or may emit other chemicals as well. When released, the emitted chemical forms a plume 122 that, over time, diffuses, concentrates, extends, and contracts according to atmospheric conditions (e.g., wind speed and direction, relative humidity, barometric pressure) over a portion of the site 100, as indicated in FIG. 1. The site also includes a set of sampler devices 160, 162, 164, 166, 168, 170, each of which may be embodied as any device capable of collecting a sample of a chemical of interest from the air for subsequent evaluation.

The site 100 includes multiple buildings 150, 152, 154, 156 which, in combination with atmospheric conditions and properties of the emission source 120 and the chemical(s) released by the emission source 120, can affect the shape and size of the plume 122 over time. Further, the movement and varying activity levels of the people 130, 132, 134, 136, 138, 140, 142, 144 present at the site affect their level of exposure and corresponding health risks relative to the chemical(s) released by the emission source 120. As such, placement of the sampler devices 160, 162, 164, 166, 168, 170 at the site 100 to collect samples of adequate quality to support an analysis of the health risks posed to the people at the site 100 is complex.

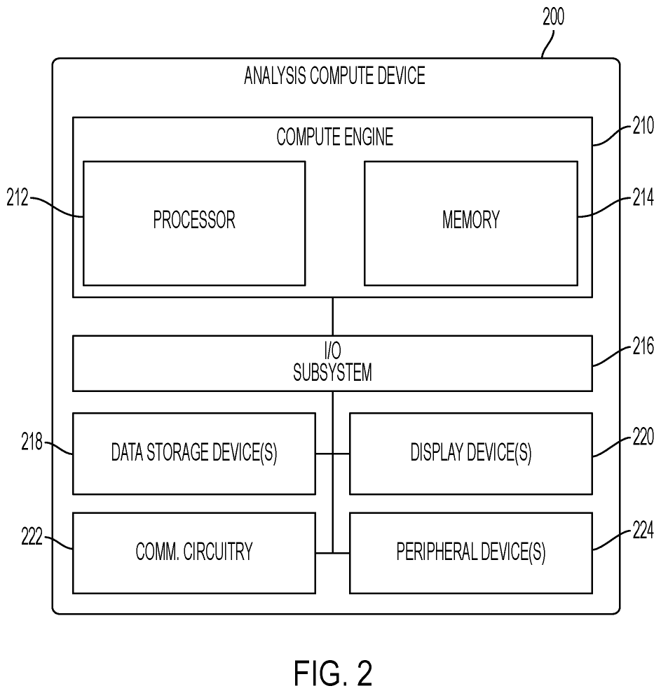

Referring now to FIG. 2, an analysis compute device 200 for producing a sampling and analysis plan (SAP), which is a plan that defines the positioning of available air sampler devices, for airborne hazards of concern over a target area (e.g., the site 100) is shown. Designed for use during the systematic planning stage of an ambient air sampling campaign within the target area (e.g., the site 100), the analysis compute device 200, in the illustrative embodiment, applies physical models and statistical analysis to data input by the user, with the goal of producing a sampling design (e.g., a SAP) setting forth recommended positioning of available air sampler devices to achieve certain statistical properties such as adequate representation of the airborne hazard and its impact on the targeted exposed population (e.g., the people 130, 132, 134, 136, 138, 140, 142, 144). As a result, the analysis compute device 200, in the illustrative embodiment, can produce useful and actionable data to inform enhanced risk assessments and a long-term medical surveillance plan for the personnel present at the site 100.

The illustrative analysis compute device 200 includes a compute engine 210, an input/output (I/O) subsystem 216, a data storage subsystem 218, one or more display devices 220, and communication circuitry 222. In some embodiments, the analysis compute device 200 may include additional components, such as peripheral devices 224 (e.g., a physical keyboard, a mouse or trackpad, etc.). Additionally, in some embodiments, one or more of the illustrative components may be incorporated in, or otherwise form a portion of, another component.

The compute engine 210 may be embodied as any type of device or collection of devices capable of performing various compute functions described herein. In some embodiments, the compute engine 210 may be embodied as a single device such as an integrated circuit, an embedded system, a field-programmable gate array (FPGA), a system-on-a-chip (SOC), or other integrated system or device. Additionally, in the illustrative embodiment, the compute engine 210 includes or is embodied as a processor 212 and a main memory 214. The processor 212 may be embodied as any type of processor capable of performing the functions described herein. For example, the processor 212 may be embodied as a single or multi-core processor(s), a microcontroller, or other processor or processing/controlling circuit. In some embodiments, the processor 212 may be embodied as, include, or be coupled to an FPGA, an application specific integrated circuit (ASIC), reconfigurable hardware or hardware circuitry, or other specialized hardware to facilitate performance of the functions described herein.

The main memory 214 may be embodied as any type of volatile (e.g., dynamic random access memory (DRAM), etc.) or non-volatile memory or data storage capable of performing the functions described herein. Volatile memory may be a storage medium that requires power to maintain the state of data stored by the medium. In some embodiments, all or a portion of the main memory 214 may be integrated into the processor 212. In operation, the main memory 214 may store various software and data used during operation such as data describing a site at which an emission source is present, meteorological data, human population and activity data, scenario simulation and sampler device placement algorithms, applications, libraries, and drivers.

The compute engine 210 is communicatively coupled to other components of the analysis compute device 200 via the I/O subsystem 216, which may be embodied as circuitry and/or components to facilitate input/output operations with the compute engine 210 (e.g., with the processor 212 and the main memory 214) and other components of the analysis compute device 200. For example, the I/O subsystem 216 may be embodied as, or otherwise include, memory controller hubs, input/output control hubs, integrated sensor hubs, firmware devices, communication links (e.g., point-to-point links, bus links, wires, cables, light guides, printed circuit board traces, etc.), and/or other components and subsystems to facilitate the input/output operations. In some embodiments, the I/O subsystem 216 may form a portion of a system-on-a-chip (SoC) and be incorporated, along with one or more of the processor 212, the main memory 214, and other components of the analysis compute device 200, into the compute engine 210.

Each data storage device 218, may be embodied as any type of device configured for short-term or long-term storage of data such as, for example, memory devices and circuits, memory cards, hard disk drives, solid-state drives, or other data storage device. Each data storage device 218 may include a system partition that stores data and firmware code for the data storage device 218 and one or more operating system partitions that store data files and executables for operating systems. One or more data storage devices 218 may store software and data used during operation of the analysis compute device 200, such as data describing a site at which an emission source is present, meteorological data, human population and activity data, scenario simulation and sampler device placement algorithms, applications, libraries, and drivers.

Each display device 220 may be embodied as any device or circuitry (e.g., a liquid crystal display (LCD), a light emitting diode (LED) display, a cathode ray tube (CRT) display, etc.) configured to display visual information (e.g., text, graphics, etc.) to a viewer (e.g., a user). Further, the display device 220 may, in some embodiments, be a touch screen (e.g., a screen incorporating resistive touchscreen sensors, capacitive touchscreen sensors, surface acoustic wave (SAW) touchscreen sensors, infrared touchscreen sensors, optical imaging touchscreen sensors, acoustic touchscreen sensors, and/or other type of touchscreen sensors) capable of detecting selections of on-screen user interface elements from the user.

The communication circuitry 222 may be embodied as any communication circuit, device, or collection thereof, capable of enabling communications over a network between the analysis compute device 200 and another device. The communication circuitry 222 may be configured to use any one or more communication technology (e.g., wired or wireless communications) and associated protocols (e.g., Ethernet, WiMAX, Bluetooth®, etc.) to effect such communication. The illustrative communication circuitry 222 includes a network interface controller (NIC). The NIC may be embodied as one or more add-in-boards, daughter cards, network interface cards, controller chips, chipsets, or other devices that may be used by the analysis compute device 200 to connect with another compute device. The peripheral devices 224 may include one or more devices, such as a mouse and/or a keyboard, capable of facilitating the input of data to the analysis compute device 200.

While shown as a single unit in FIG. 2, the components of the analysis compute device 200 may be located in multiple housings but communicatively coupled together (e.g., via the I/O subsystem). Further, it should be appreciated that the analysis compute device 200 may include other components, sub-components, and devices commonly found in a computing device, which are not discussed above in reference to the check in compute device 200 and not discussed herein for clarity of the description. Additionally, one or more of the sampler devices 160, 162, 164, 166, 168, 170 may include components similar to those described above with reference to the analysis compute device 200.

As referenced above, a key function of the analysis compute device 200 is to generate a statistically defensible SAP by integrating and analyzing meteorological data, hazard emission rates, population movement and physical activity levels, other datasets, and onboard algorithms. The resulting SAP, in the illustrative embodiment, specifies the date and start time, sampling durations, and sampler locations which, when implemented, lead to data that achieve target statistical properties to aid personnel in determining where and when to position available ambient air sampler devices (e.g., the sampler devices 160, 162, 164, 166, 168, 170), thereby leading to higher quality sampling data and improved risk assessments. An illustrative method 300 that may be executed by the analysis compute device 200 to satisfy the above goals is described below.

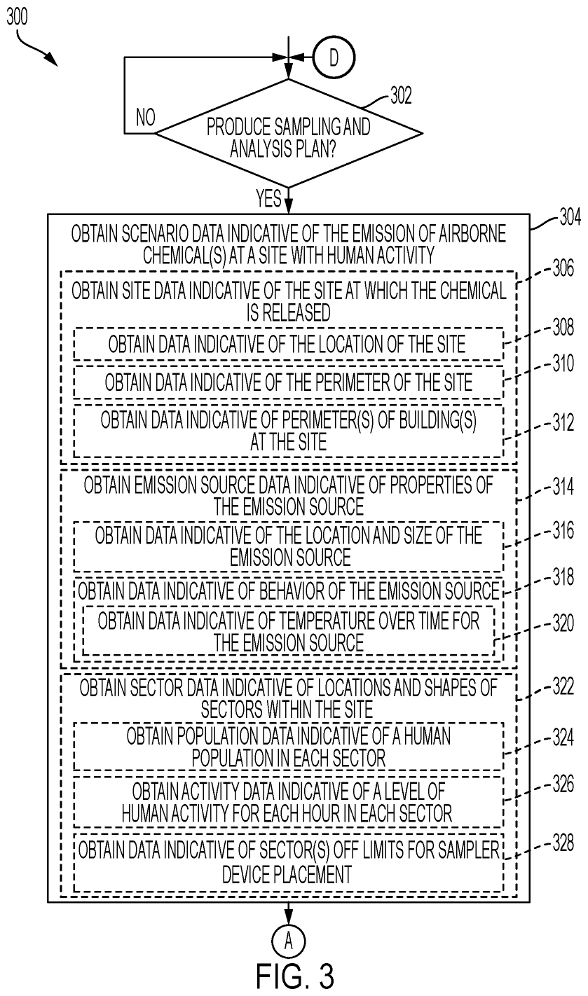

Referring now to FIG. 3, in operation, the analysis compute device 200 may perform a method 300 for producing a sampling and analysis plan. The method 300 begins with block 302 in which the analysis compute device 200 determines whether to produce a sampling and analysis plan. In doing so, the analysis compute device 200 may determine whether a user request has been received to produce a sampling and analysis plan. For example, a user (not shown) may initiate an application (e.g., software) on the analysis compute device 200 to begin the process of producing a sampling and analysis plan. In doing so, the analysis compute device 200 may obtain information from the user, such as the user's name and contact information (e.g., email address, physical address, phone number, role, organization, etc.) as a point of contact associated with a sampling and analysis plan. In other embodiments, the analysis compute device 200 may make the determination of whether to produce a sampling and analysis plan based on other factors. Regardless, in response to a determination to produce a sampling and analysis plan, the method 300 advances to block 304 in which the analysis compute device 200, in the illustrative embodiment, obtains scenario data which may be embodied as any data (e.g., input by a user through a user interface, read from a file or other data source, etc.) that is indicative the emission of one or more airborne chemicals at a site with human activity (e.g., a human population performing activities).

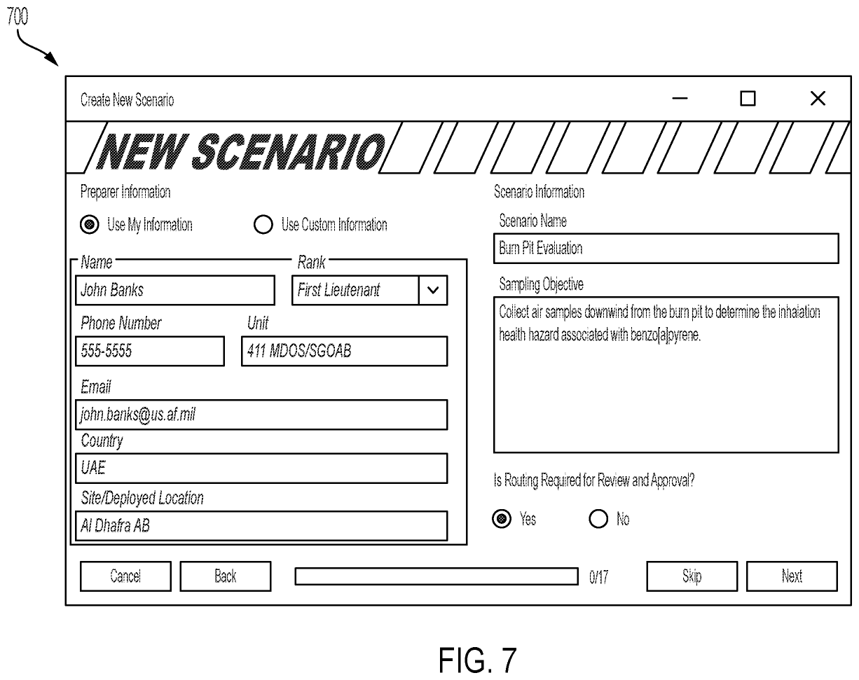

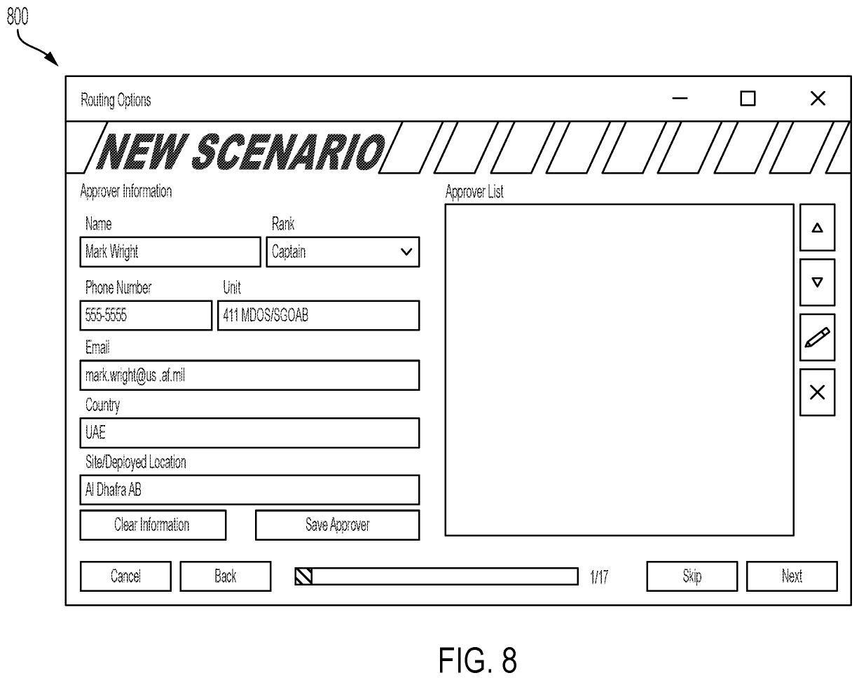

Referring now to FIG. 7, the analysis compute device 200 may present a user interface 700 for creating a new scenario. In the user interface 700, a progress bar displays a progress of 0/17. The user interface 700 also includes a set of radio buttons to enable the user to select preexisting information about the user as the preparer of a new scenario and sampling and analysis plan, or to enter custom information about the user/preparer. More specifically, in the illustrative embodiment, the user may select a radio button labeled “Use My Information” in which case the analysis compute device 200 may display information previously entered into the analysis compute device 200 regarding the user or preparer. Alternatively, the user may select a radio button entitled “Use Custom Information” in which case the analysis compute device 200 may collect new information regarding the user or preparer of the scenario and sampling and analysis plan. In either case, the information regarding the user or preparer may include a name (e.g., first and last name), rank or role, phone number, email address, country, organization that the user or preparer is affiliated with, a name of a site that the user or preparer is deployed to and/or other information indicative of the user or preparer of the sampling and analysis plan. Still referring to FIG. 7, the illustrative user interface 700 additionally includes a field in which the user enters a name of the scenario to be created and an objective for the scenario (e.g., “collect air samples downwind from the burn pit to determine the inhalation health hazard associated with benzo[a]pyrene”). Referring now to FIG. 8, the analysis compute device 200 may additionally present a user interface 800 to obtain information regarding a reviewer (e.g., name, rank or role, phone number, email address, organization, country, site or deployment location) who will review and approve the resulting sampling and analysis plan. In the illustrative embodiment, the user interface 800 includes a progress bar indicating a progress of 1/17. The user may save information regarding the specified reviewer and enter information regarding one or more additional reviewers via the user interface 800. Each reviewer's name, in the illustrative embodiment, is added to a corresponding list in the user interface 800 as they are entered by the user and stored by the analysis compute device 200.

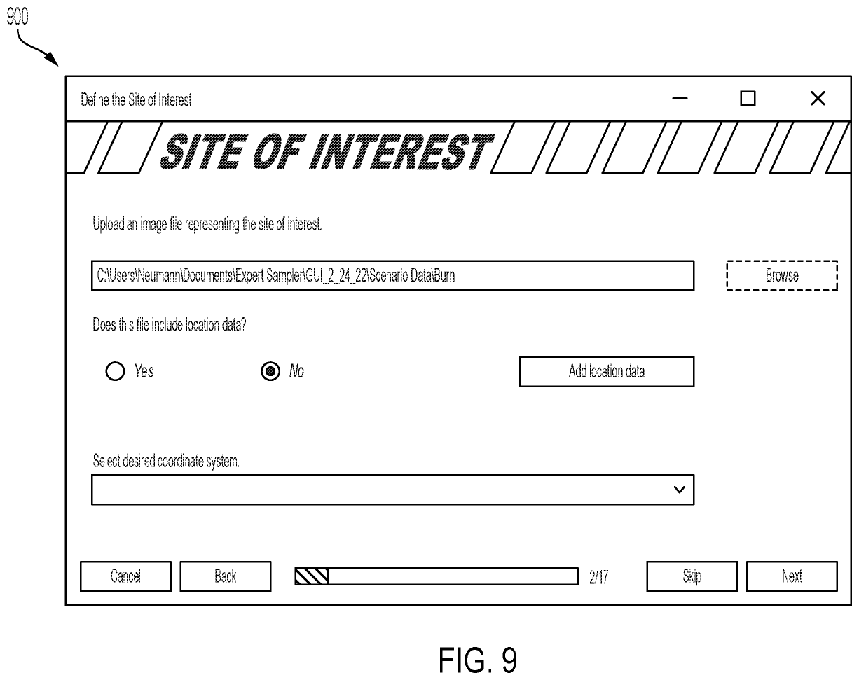

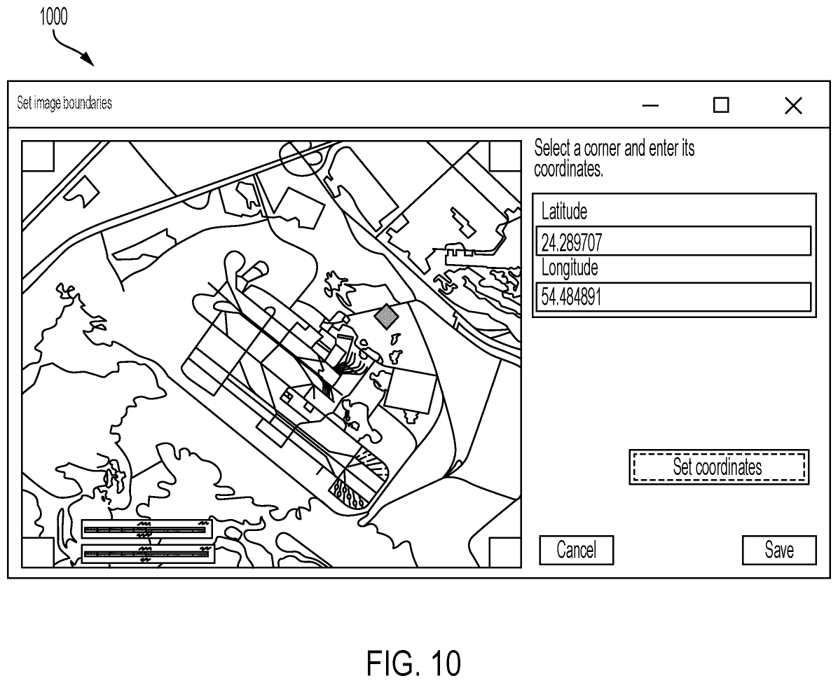

Referring back to FIG. 3, as indicated in block 306, the analysis compute device 200, in the illustrative embodiment, obtains site data indicative of the site at which the chemical is to be released. In doing so, the analysis compute device 200 may obtain data indicative of the location of the site, the perimeter of the site, and the perimeters of any buildings at the site (e.g., within the perimeter of the site), as indicated in blocks 308, 310, and 312. Referring briefly to FIG. 9, the analysis compute device 200 may present a user interface 900 to enable the user to provide information regarding the site, also referred to as the “site of interest.” The user interface 900 includes a progress bar indicating a progress of 2/17. The user may select a browse button to locate a folder containing an image (e.g., a .jpg file, a .png file, a .bmp file, or similar file containing image data) of the site. The user interface 800, in the illustrative embodiment, also includes a set of radio buttons through which the user specifies whether the image file identified above includes image data. If it does not, the user may select a button to add location data manually. In the illustrative embodiment, in response to determining that the user selected the button to add location data, the analysis compute device 200 presents a user interface 1000 shown in FIG. 10. In the user interface 1000, the analysis compute device 200 displays the site based on the image file that was specified through the user interface 900. Additionally, the user interface 1000 displays four squares, each located in a respective corner of the image (e.g., upper left, upper right, lower left, lower right). The user may iteratively select a corner (e.g., by tapping on it via a touch screen or clicking on it using a mouse) and enter a corresponding set of latitude and longitude coordinates defining the location of that particular corner of the site in the world. The analysis compute device 200 causes each square to change from one color to another color (e.g., from red to green) to indicate that the corresponding square has been selected by the user and the coordinates for the square have been entered. In the illustrative embodiment, the user then selects a save button to cause the analysis compute device 200 to store the coordinates (e.g., in the data storage 218). Subsequently, in the illustrative embodiment, the analysis compute device 200 redisplays the user interface 900 and the user selects a next button to proceed to another stage.

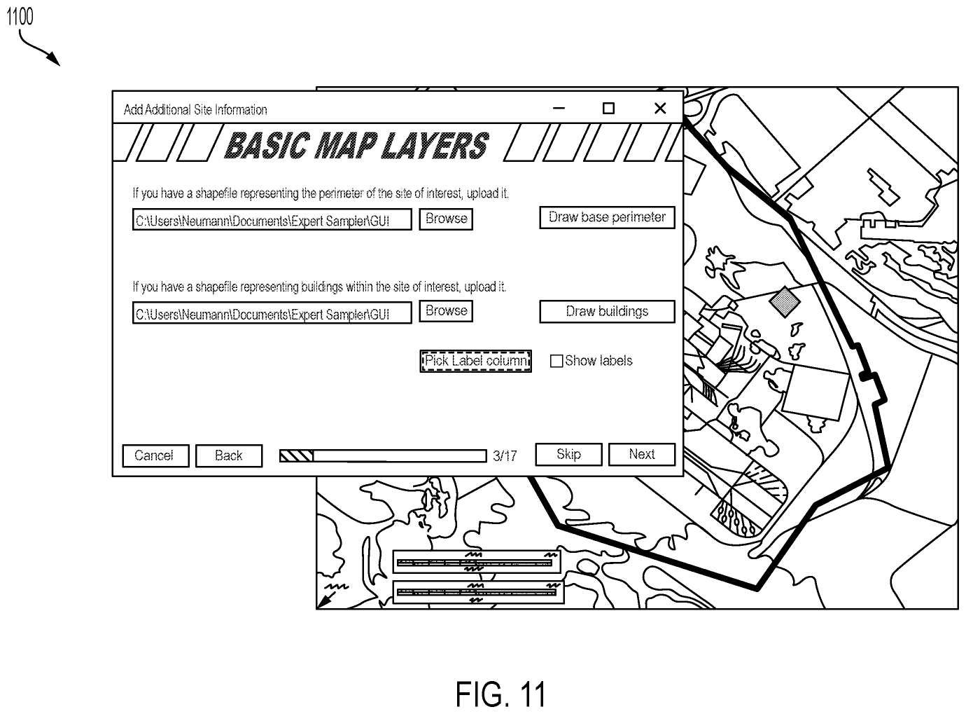

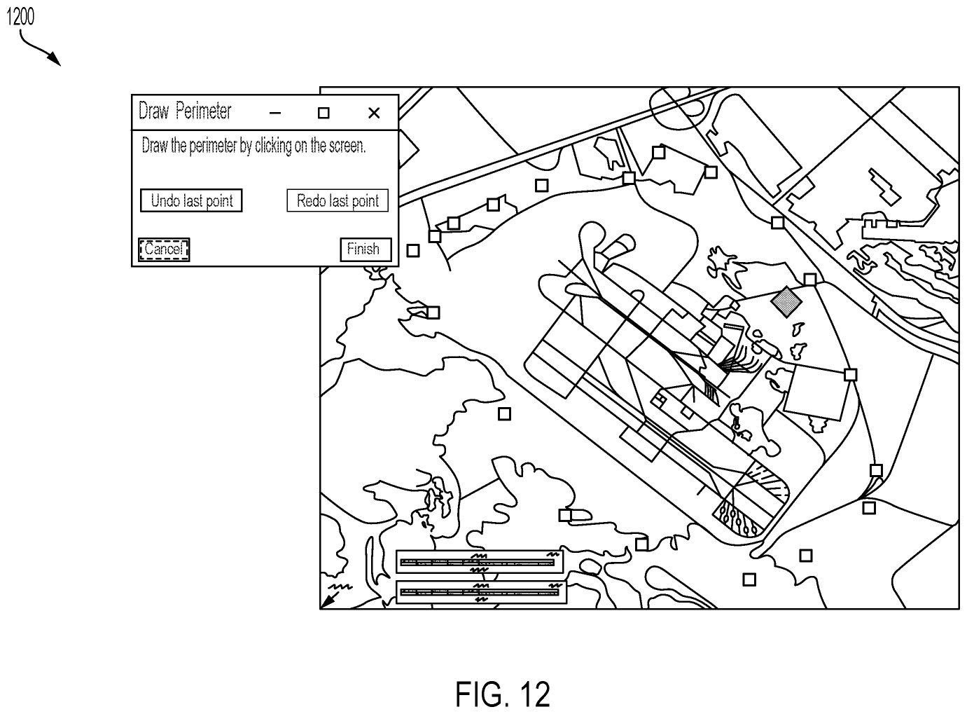

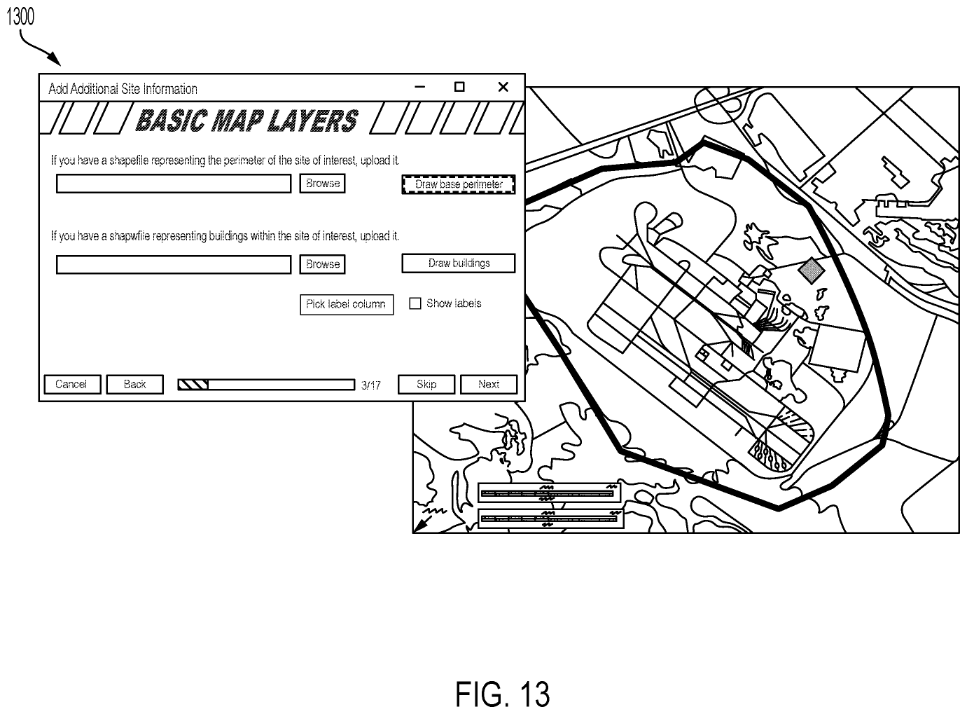

Subsequently, the analysis compute device 200, in the illustrative embodiment, presents a user interface 1100 shown in FIG. 11, through which the user defines the perimeter of the site (e.g., the boundary within which all sampler devices will be positioned) and any buildings located within the perimeter. The user interface 1100 includes a progress bar indicating a progress of 3/17. To define the perimeter of the site, either a GIS shape (.shp) file can be loaded by the analysis compute device 200 or a perimeter can be drawn manually on the displayed site map (e.g., through a touch screen or a mouse). Similarly, buildings can be input via a GIS shape (.shp) file or can be drawn manually (e.g., through a touch screen or a mouse) and labeled on the image of the site. If the user elects to draw the perimeter of the base, rather than specifying a file with that information, the user selects a corresponding button (e.g., “Draw base perimeter”) and the analysis compute device 200 displays a user interface 1200 shown in FIG. 12. On the displayed image of the site, the user selects positions on the image of the site. In response to each position selection, the analysis compute device 200 displays a yellow point representing the selected position. The user then selects a finish button to indicate that the perimeter of the site has been entered. In response, the analysis compute device 200 fills in the remainder of the perimeter by connecting the displayed points with a blue line as indicated in the user interface 1300 shown in FIG. 13.

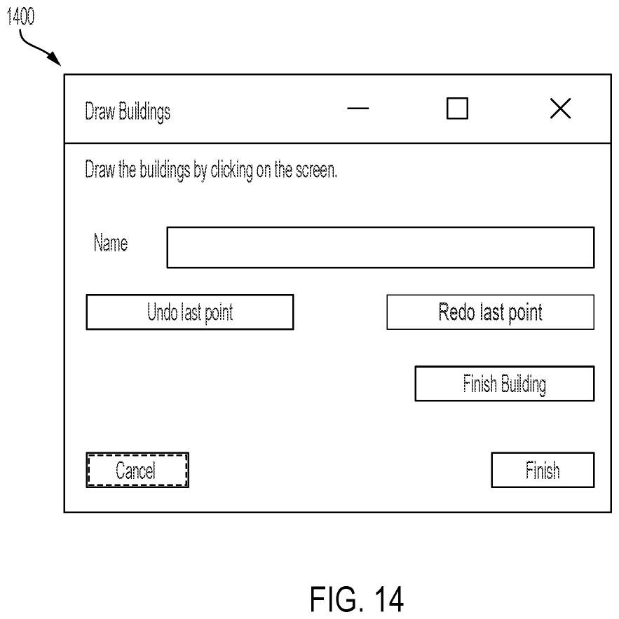

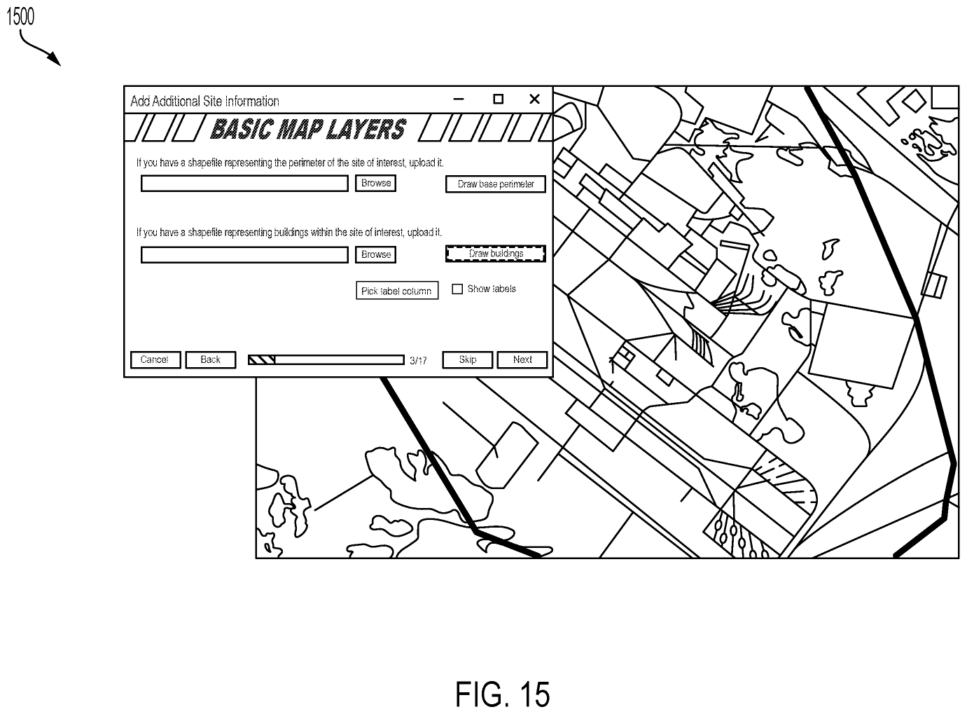

If the user elects to manually enter the locations of the buildings, the user selects a corresponding button (e.g., “Draw buildings”) and the analysis compute device 200 displays the user interface 1400 shown in FIG. 14 along with the image of the site. The user draws, on the image of the site, the perimeter of each building to be stored by the analysis compute device 200. In the illustrative embodiment, the user also enters the name for a given building in a corresponding name field in the user interface 1400. When the user has finished drawing the perimeter of and naming a given building, the user selects a “Finish Building” button. In response, the analysis compute device 200 stores the perimeter and name of the building and enables the user to enter the perimeter and name of another building. The analysis compute device 200 displays the name and perimeter for each building defined by the user, as shown in the user interface 1500 of FIG. 15.

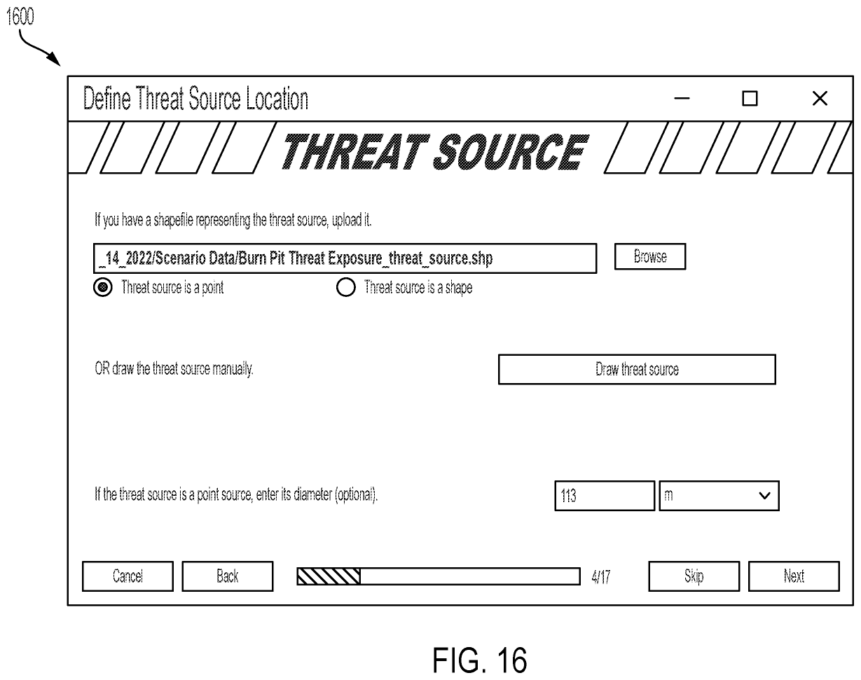

Referring back to FIG. 3, as indicated in block 314, the analysis compute device 200 obtains emission source data which may be embodied as any data that is indicative of properties of the emission source. In the illustrative embodiment, the analysis compute device 200 obtains data indicative of the location and size of the emission source, as indicated in block 316. Referring now to the user interface 1600 of FIG. 16, to specify the threat or emission source, the user may enter the location of a GIS shape (.shp) file containing the location and size of the source. If the user provides the location of a GIS shape file, the user also selects from a set of radio buttons whether the emission source is point or a shape (indicating a larger surface area). If the emission source is a point source, the analysis compute device 200 prompts the user to specify the diameter along with the units of measurement of the diameter. Alternatively, the user can draw the emission source manually, in which case the analysis compute device 200 determines the diameter of the emission source based on the drawing. If the user elects to draw the emission source, the analysis compute device 200 guides the user through a drawing process similar to the process described above for manually drawing the perimeter of the site and/or buildings located at the site. The user interface 1600 includes a progress bar indicating a progress of 4/17.

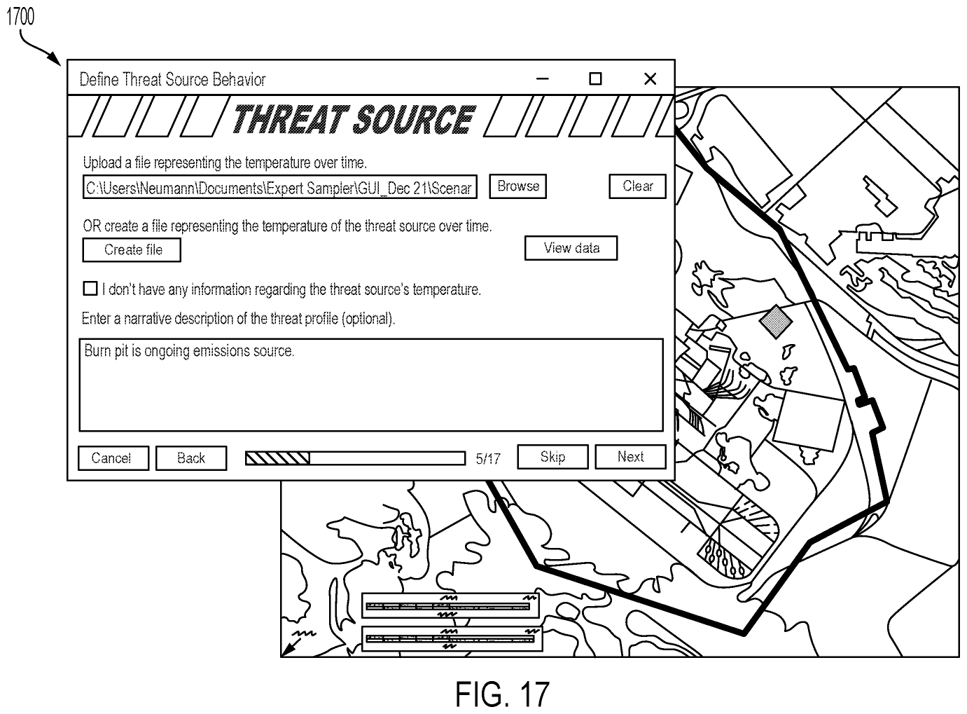

Further, and as indicated in block 318, the analysis compute device 200 obtains data indicative of behavior of the emission source. In doing so, the analysis compute device 200, in the illustrative embodiment, obtains data indicative of temperature over time for the emission source, as indicated in block 320. Referring now to FIG. 17, to obtain behavior data for the emission source, the analysis compute device 200 displays the user interface 1700, which includes a progress bar displaying a progress of 5/17. The behavior of the emission source is defined by a set of parameters including a year (in YYYY format), day of year, temperature at a given hour (24-hours) and uncertainty of temperature (%). The information may be specified in one or two ways. One way is for the user to specify a .csv (comma separated value) or Microsoft Excel file that contains the information in a format that the analysis compute device 200 is configured to read. In the illustrative embodiment, the user may select a browser button to locate and specify a location of the .csv or Excel file containing the threat source behavior data. The user may also specify a description of the threat profile in a text box at the bottom of the user interface 1700. Alternatively, the user may enter the data into separate on-screen fields to create a corresponding data file of the emission source behavior data.

The analysis compute device 200, in obtaining scenario data, also obtains sector data which may be embodied as any data that is indicative of the location(s) and shape(s) of any sectors within the site, as indicated in block 322. In obtaining the sector data, the analysis compute device 200 illustratively obtains population data which may be embodied as any data that is indicative of the human population in each sector (e.g., the number of people, the percentage of a known quantity of people, etc.), as indicated in block 324. The analysis compute device 200 also illustratively obtains activity data which may be embodied as any data indicative of the level of human activity for each hour (e.g., each hour of a repeating 24 hour period) in each sector, as represented in block 326. Further, in some embodiments, the analysis compute device 200 may obtain data that is indicative of one or more sectors that are off limits for sampler device placement (e.g., in which sampler devices are prohibited), as indicated in block 328.

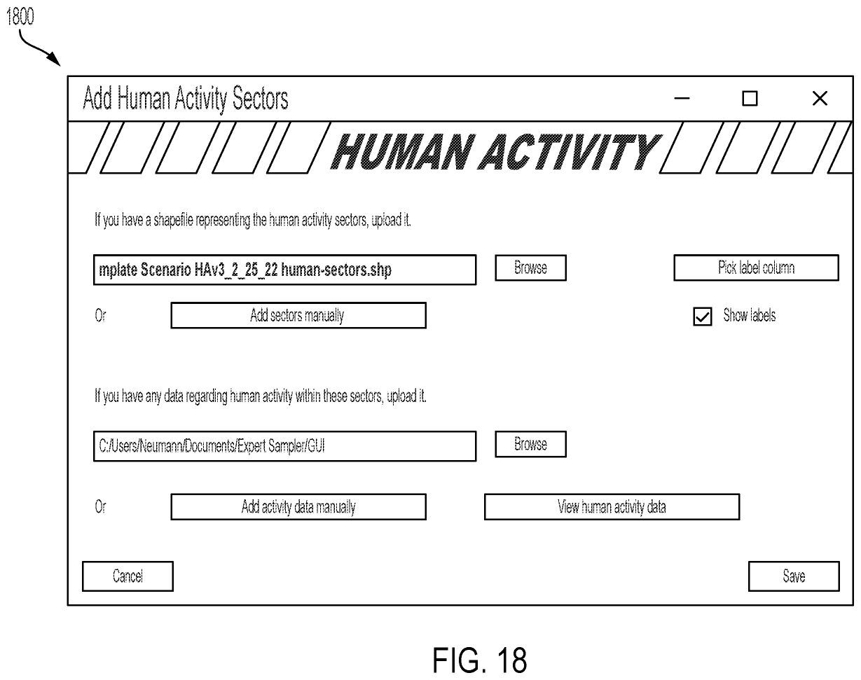

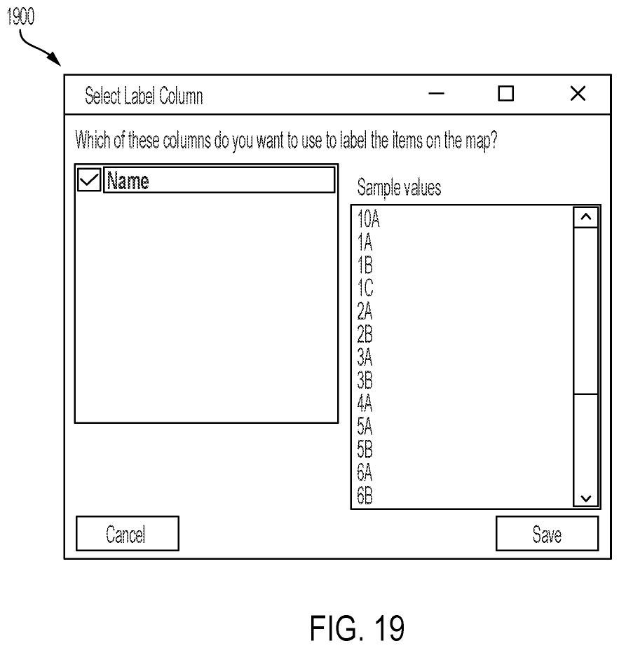

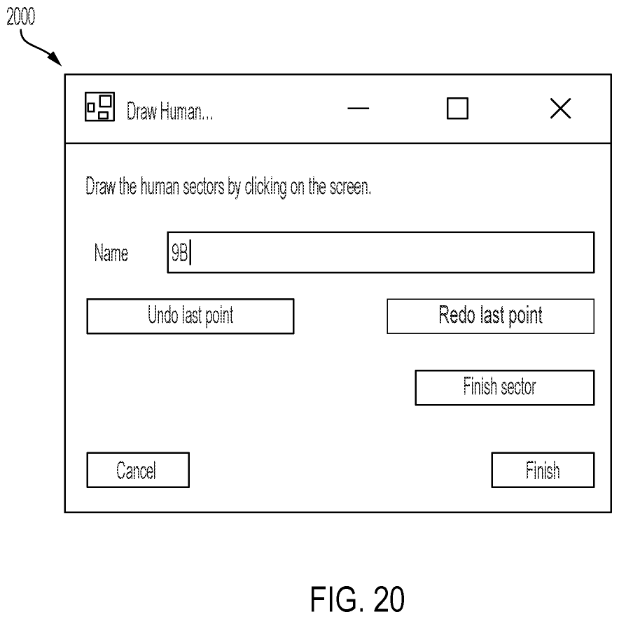

Referring now to the user interface 1800 shown in FIG. 18, a user can provide, to the analysis compute device 200, data regarding human activity by inputting existing data files (e.g., a GIS shape file that defines the sectors and a .csv file of the human activity percentages and activity levels) or drawing the sectors manually and adding activity level data using an “add activity data manually” button. If the sectors are defined within a GIS shape file, the user clicks on a browse button to specify the location of the GIS shape file containing the perimeters of the sectors. Once the sector perimeters have been defined, the user clicks on a “Pick label column” button. In response, the analysis compute device 200 displays the user interface 1900 shown in FIG. 19. In a left field in the user interface 1900, the user selects the check box next to “Name.” The values for the sector labels are listed in the right field (as stored within the GIS shape file for the sectors). The user the selects a save button in the user interface 1900. If the user selects the “show labels” check box in the user interface 1800, the analysis compute device 200 causes the sector labels to be displayed on the image of the site, within each corresponding sector. In the absence of a shape file, the user may select the “Add sectors manually” button in the user interface 1800 In response, the analysis compute device 200 presents the user interface 2000 shown in FIG. 20. The user then manually specifies the parameters of a sector on the site map in the same manner as for defining the perimeters of buildings, described above. Additionally, the user assigns a label to the sector within the “Name” field of the user interface 2000. The user then selects the “Finish sector” button when finished and may repeat the above process for any additional sectors to be added, before pressing the “Finish” button.

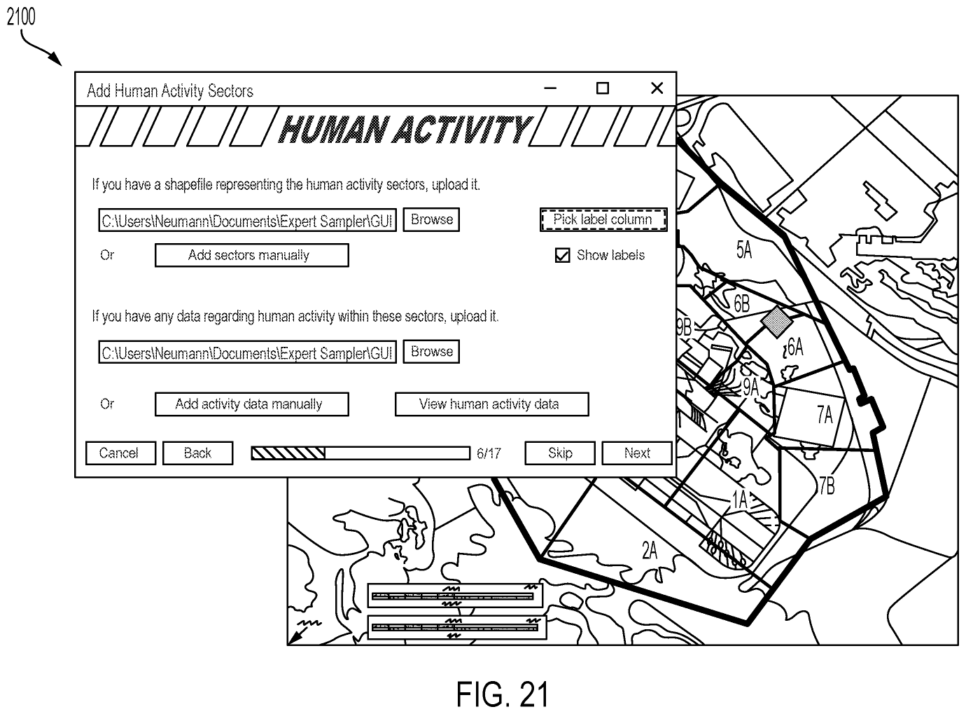

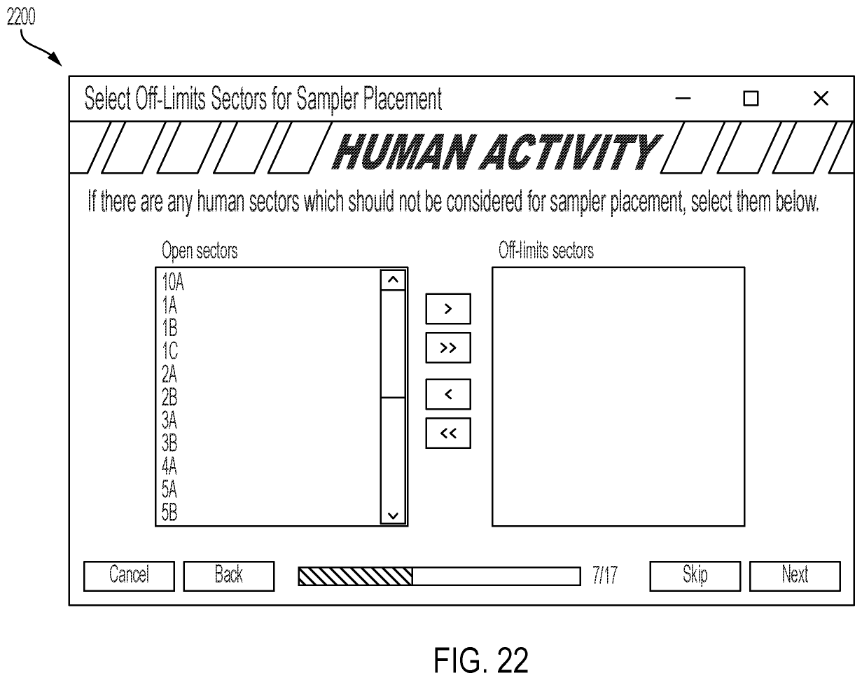

Back in the human activity user interface, and as shown in the illustration 2100 in FIG. 21, which shows a progress bar indicating a progress of 6/17, the user inputs information on an activity level for each sector on an hourly basis within a typical 24-hour period. The user may select a browse button to specify the location of a .csv data file containing human activity data (e.g., percentages of total population within each sector and activity level). In the absence of a .csv data file, the data can be manually entered by selecting the “add activity data manually” button and entering the data, which the analysis compute device 200 then stores. In some embodiments, the activity levels may be categorized numerically. For example, 0 may represent no activity, 1 may represent low activity (consistent) (e.g., administrative areas, sleeping), 2 may represent low-medium activity (varies) such as aircraft maintenance hangers and housing, 3 may represent medium activity (consistent) such as flightline and aircraft maintenance hangars, 4 may represent medium-high activity (varies) such as flightline or manual construction work, and 5 may represent high activity (consistent) such as flightline activity. Referring now to FIG. 22, the analysis compute device 200 may present a user interface 2200 that enables the user to identify any sectors which should not be considered for sampler device placement (e.g., off limits to sampler device placement algorithm executed by the analysis compute device 200). In the user interface 2200, a progress bar indicates a progress of 7/17. The user may select one or more sectors listed in the left list of total sectors and move them to the list to the right of sectors that are off limits. The analysis compute device 200, in response, stores data indicative of the sectors that are off limits for sampler device placement.

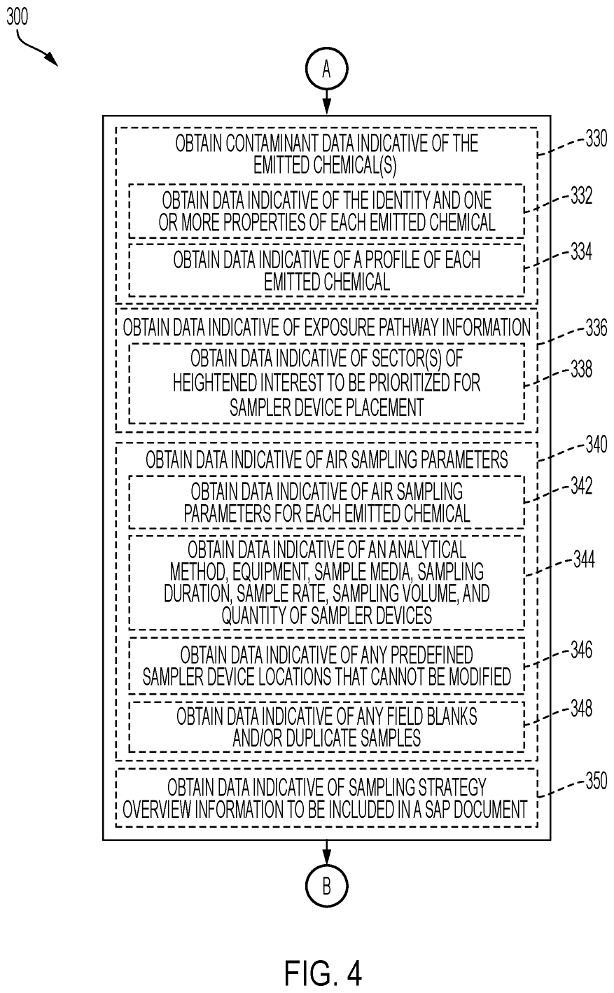

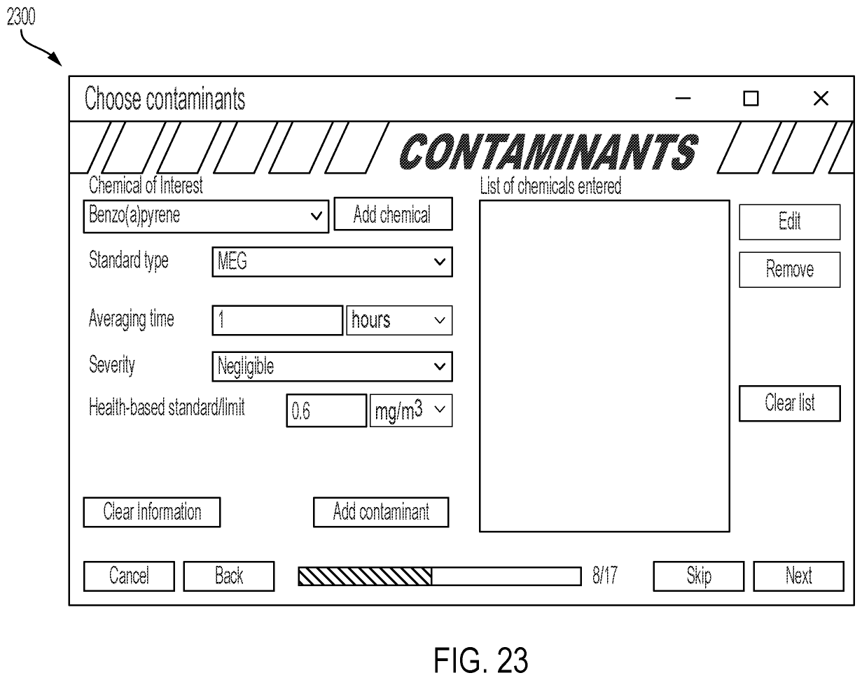

Referring now to FIG. 4, in obtaining scenario data, the analysis compute device 200 also obtains contaminant data, which may be embodied as any data indicative of the emitted chemical(s) at the site, as indicated in block 330. In obtaining the contaminant data, the analysis compute device 200 illustratively obtains data indicative of the identity (e.g., name) and one or more properties of each emitted chemical, as represented in block 332. Further, in block 334, the analysis compute device 200 may obtain data indicative of a profile of each emitted chemical. Referring now to FIG. 23, the analysis compute device 200 in the illustrative embodiment presents a user interface 2300 to enable the user to enter contaminant data. The user interface 2300 includes a progress bar indicating a progress of 8/17. Under the “chemical of interest,” the user selects a chemical from a drop-down box. For the specified chemical, the analysis compute device 200 populates a set of fields below the chemical name with information regarding the chemical. The user does not need to specify the information but can edit the information if desired. The data includes a standard type, an averaging time, a severity, and a health-based standard/limit. The user then selects an “add contaminant” button. In response, the analysis compute device 200 moves the chemical name to the field labeled “list of chemicals entered” to the right panel. The user repeats the above steps for any additional chemicals of interest.

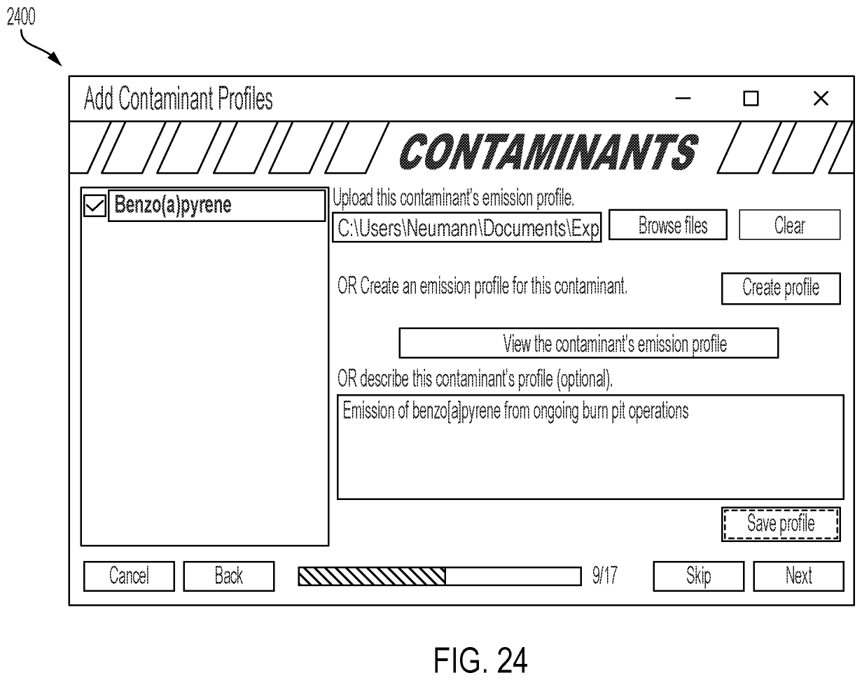

Subsequently, the analysis compute device 200 may present a user interface 2400 shown in FIG. 24, for contaminant profile information. The selected chemical(s) appear along the left side of the user interface with each name preceded by a check box. The user interface 2400 includes a progress bar with a progress of 9/17. Using the user interface 2400, the user selects a check box for one of the chemicals appearing in the list, the selects a browse button to specify the location of a .csv data file containing information on the contaminant (chemical). The data file contains parameters (columns) representing year, day of year, time (hours), emission rate (g/s), and an uncertainty value associated with the emissions rate (e.g., as a percentage of the rate). In the absence of a .csv data file, the data may be manually entered if the user selects the “create profile” button and manually enters the data in a separate user interface. The analysis compute device 200, in response, saves the entered data in a corresponding data file (e.g., a .csv data file).

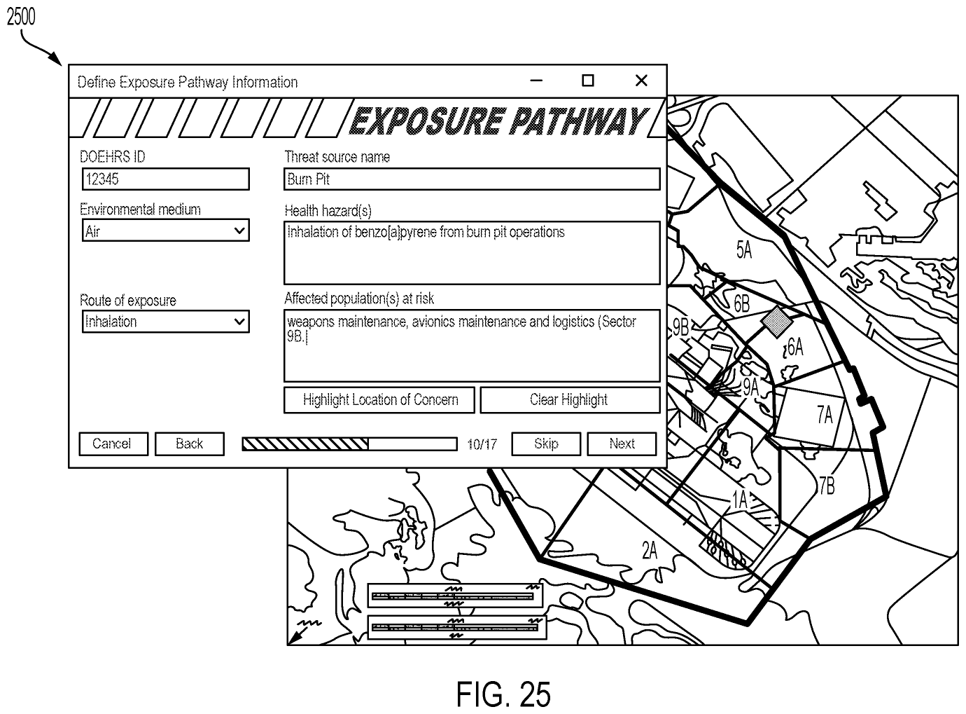

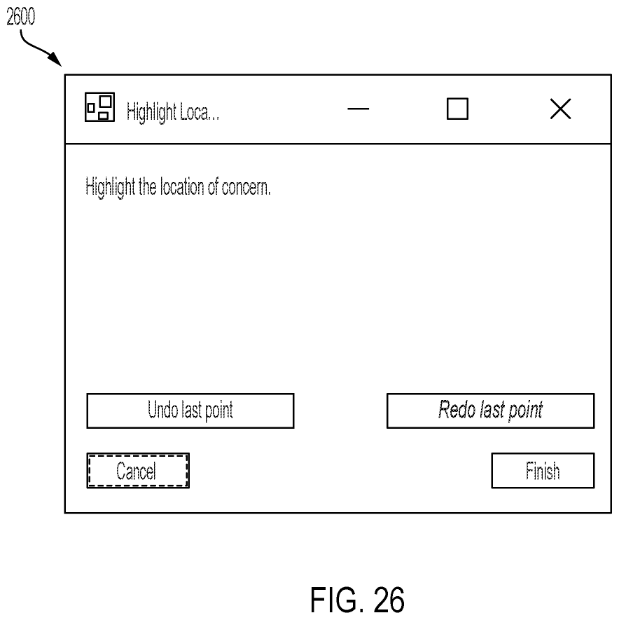

Referring back to FIG. 4, while still obtaining the scenario data, the analysis compute device 200 may also obtain data that is indicative of exposure pathway information, as indicated in block 336. In doing so, the analysis compute device 200 may also obtain data indicative of one or more sectors of heightened interest (e.g., concern) that should be prioritized for sampler device placement, as indicated in block 338. To obtain exposure pathway information, the analysis compute device 200 may present a user interface 2500 shown in FIG. 25, which includes a progress bar indicating a progress of 10/17. The user interface 2500 includes a DOEHRS-IH ID to be assigned to the SAP. The ID may already be listed within DOEHRS-IH, or it may need to be added manually after the profile is complete. The user enters information for each of six fields listed in the user interface 2400 including the DOEHRS-IH ID, a threat source name, an environmental medium (drop down), health hazard(s), route of exposure (drop down), and affected population(s) at risk. The user then selects a “highlight location of concern” button to place a colored dot (e.g., green) within sector(s) that are of greatest interest for exposure to the threat source (and thus are prioritized for sampler device placement in the SAP as the population of the selected sector(s) is considered to be at heightened risk for exposure). FIG. 26 illustrates a user interface 2600 that the analysis compute device 200 displays to prompt the user to highlight (e.g., select on the image of the site) a location (sector) of concern.

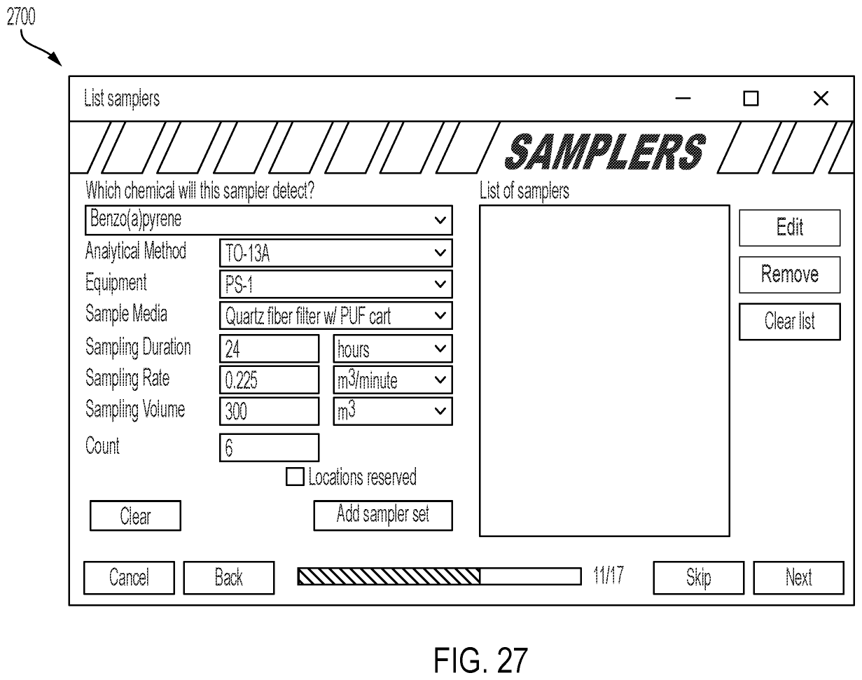

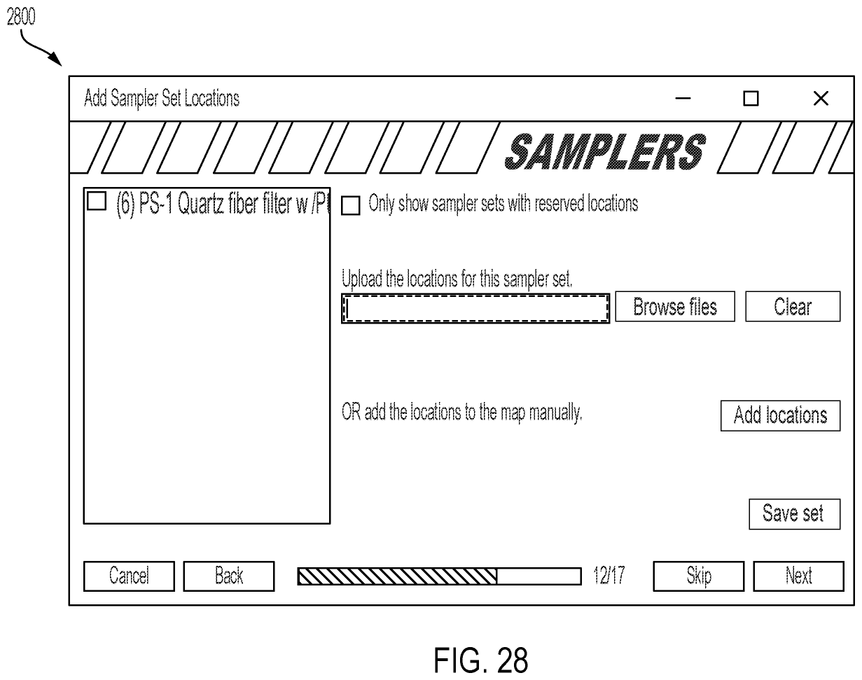

Referring back to FIG. 4, the analysis compute device 200, in block 340, may obtain data indicative of air sampling parameters. In doing so, and as indicated in block 342, the analysis compute device 200 may obtain data indicative of air sampling parameters for each chemical (e.g., on a per chemical basis, rather than a generalized set of air sampling parameters). Additionally, the analysis compute device 200 may obtain data indicative of an analytical method, equipment, sample media, sampling duration, sample rate, sampling volume, and the quantity of sampler devices, as represented in block 344. Further, in obtaining data indicative of air sampling parameters, the analysis compute device 200 may obtain data indicative of any predefined sampler device locations that cannot be modified (e.g., fixed location(s) for sampler device(s)), as indicated in block 346. The analysis compute device 200 may also obtain data indicative of any field blanks and/or duplicate samples, in block 348. Referring now to FIG. 27, the analysis compute device 200 may display a user interface 2700 for obtaining air sampling parameter data. The user interface 2700 includes a progress bar indicating a progress of 11/17. The user specifies a chemical of interest by selecting the corresponding check box. For the specified chemical, the user enters information related to the proposed sampling process using either the drop-down boxes or by entering information into the text boxes. The information includes analytical method (drop-down), equipment (drop-down), sample media (drop-down), sampling duration, sampling rate, sampling volume, and count (e.g., number of sampling devices of the specified type). In some situations, it may be necessary to position one or more sampler devices at pre-specified locations. These sampler devices would not be included in the sampler device location algorithm executed by the analysis compute device 200, as their locations are treated as fixed and unmodifiable. If any sampler devices are to be placed at pre-determined locations, the user selects the “Locations reserved” check box. The user selects the “Add sampler set” button and, in response, the analysis compute device 200 transfers the sampling and method information into the list of samplers field on the right. If a different sampling method and equipment type are used, then multiple sampling methods with prescribed equipment can be entered. The user then clicks on the “Next” button to proceed to an add sampler set locations user interface 2800, which is illustrated in FIG. 28. The user interface 2800 includes a progress bar that indicates a progress of 12/17. If sampler devices are to be reserved for pre-specified locations, those locations are added in the user interface 2800, either by inputting a GIS shape file or by specifying the locations manually (e.g., selecting the locations on an image of the site, using a mouse or taps on a touch screen, etc.).

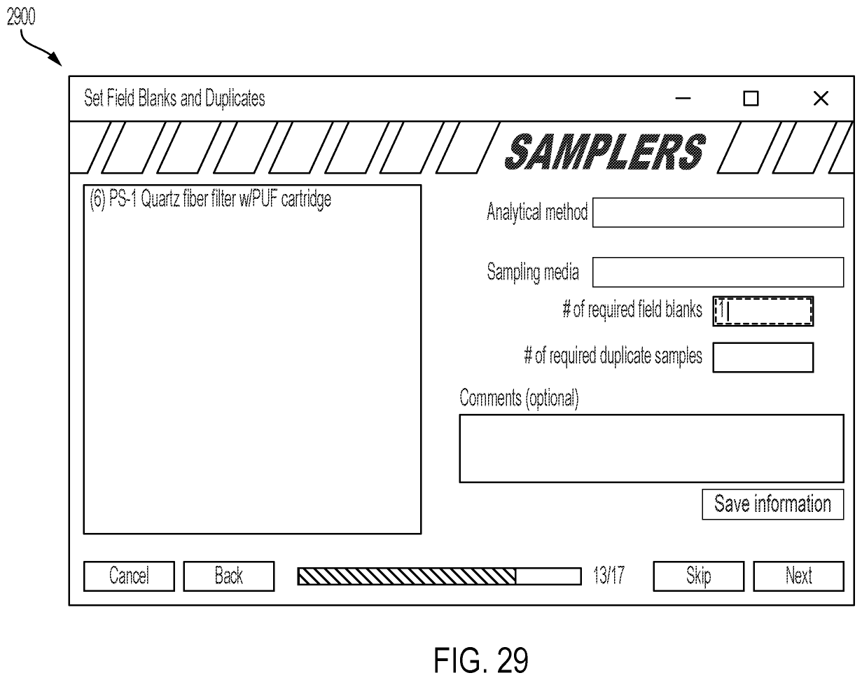

In a subsequent user interface 2900 shown in FIG. 29, a progress bar indicates a progress of 13/17. In the user interface 2900, the user may enter a number of field blanks and/or duplicates for the given sampling set. The analysis compute device 200 populates the list of sampler devices on the left side of the user interface 2900. If desired, the user may enter comments in a comments field, such as a justification if more field blanks or duplicates are specified than the sampling method might require.

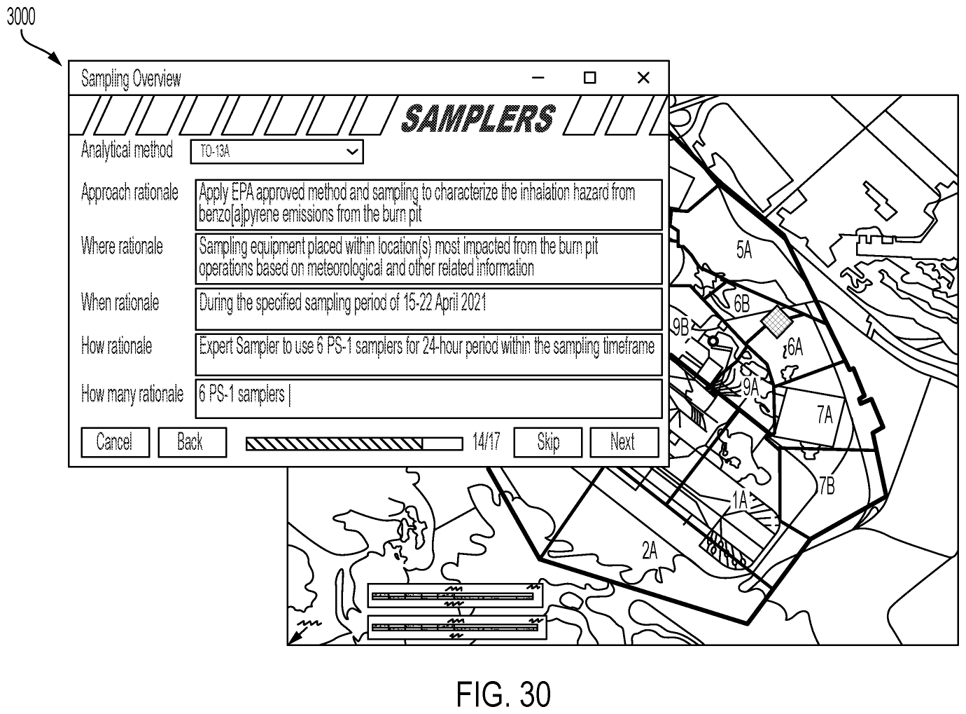

Referring back to FIG. 4, the analysis compute device 200 may also obtain data indicative of sampling strategy overview information to be included in a sampling and analysis plan (SAP) document, as indicated in block 350. To obtain the sampling strategy overview information, the analysis compute device 200, in the illustrative embodiment, displays a user interface 3000 represented in FIG. 30. The user interface 3000 includes a progress bar indicating a progress of 14/17. The user interface 3000 includes several text fields which allow the user to provide a series of rationale statements for each analytical method selected. This text will be included in the SAP generated by the analysis compute device 200. The user selects an analytical method from those specified above in the drop-down list. The user then enters information on the “approach” rationale. The user also enters information on the “where” rationale, the “when” rationale, the “how” rationale, and the “how many” rationale, in the corresponding text fields.

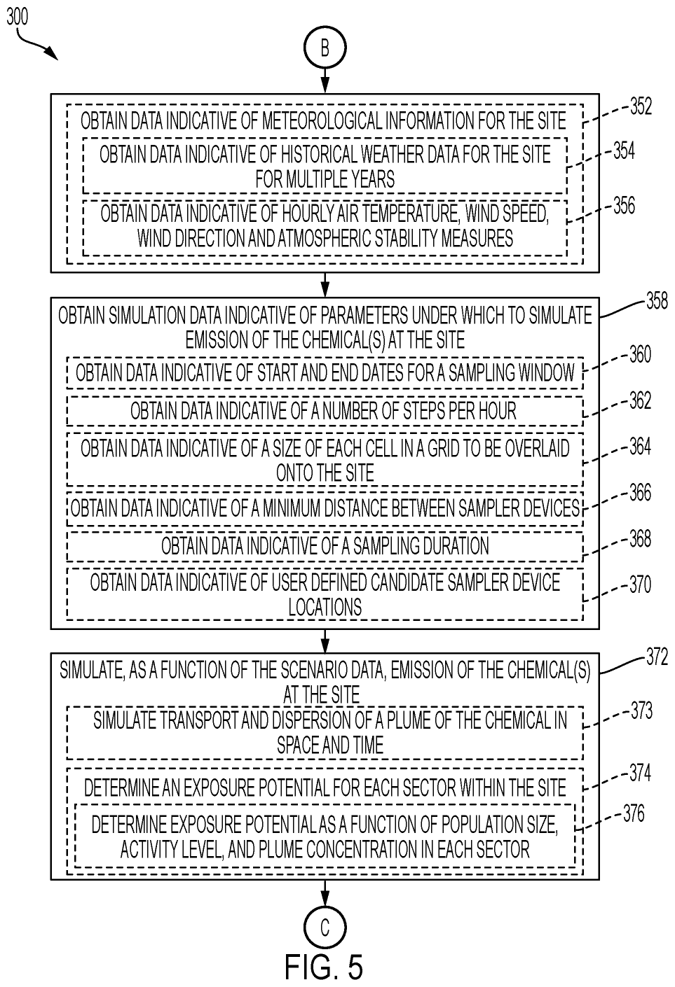

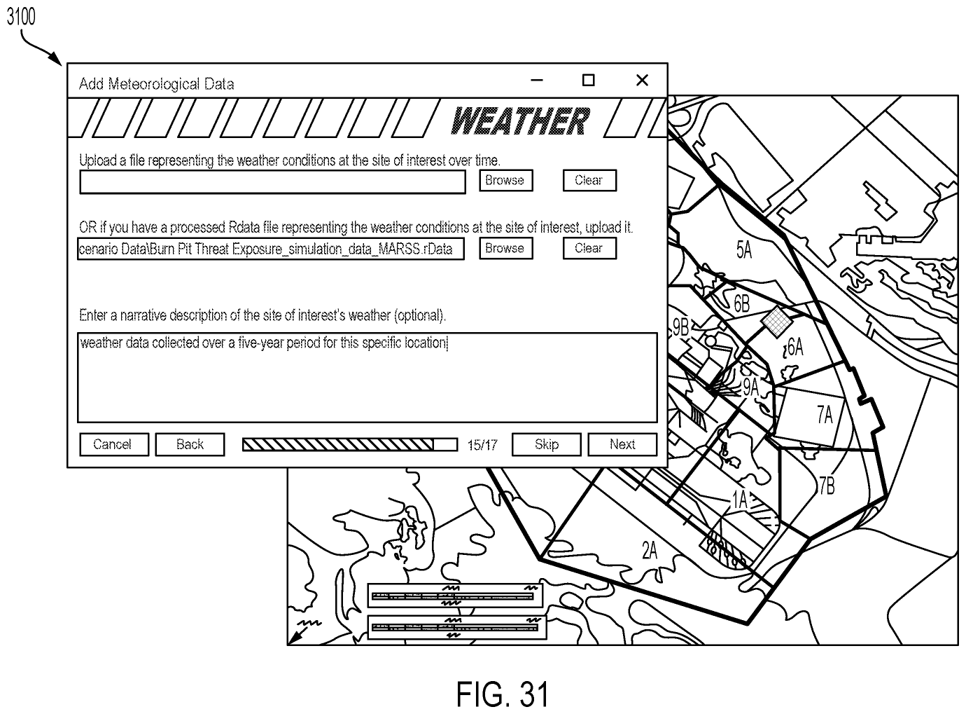

Referring now to FIG. 5, in obtaining scenario data the analysis compute device 200 also obtains data indicative of meteorological information for the site, as indicated in block 352. In doing so, the analysis compute device 200 may obtain data indicative of historical weather for the site for multiple years (e.g., the past five years), as indicated in block 354. In the illustrative embodiment, the analysis compute device 200 obtains data indicative of hourly air temperature, wind speed, wind direction and atmospheric stability measures for the site, as indicated in block 356. Referring now to FIG. 31, the analysis compute device 200 may display a user interface 3100 for entering meteorological information for the site. The user interface 3100 includes a progress bar indicating a progress of 15/17. The user selects a browser button to specify the location of a data file containing the meteorological data. In the illustrative embodiment, the data file is an R data file (e.g., formatted for use in R). However, in other embodiments, the data file may be in another format, such as a .csv format (comma separated values). The user may, if desired, input a narrative description on typical weather patterns at the site. This is optional but useful for documenting the source and nature of the meteorological data.

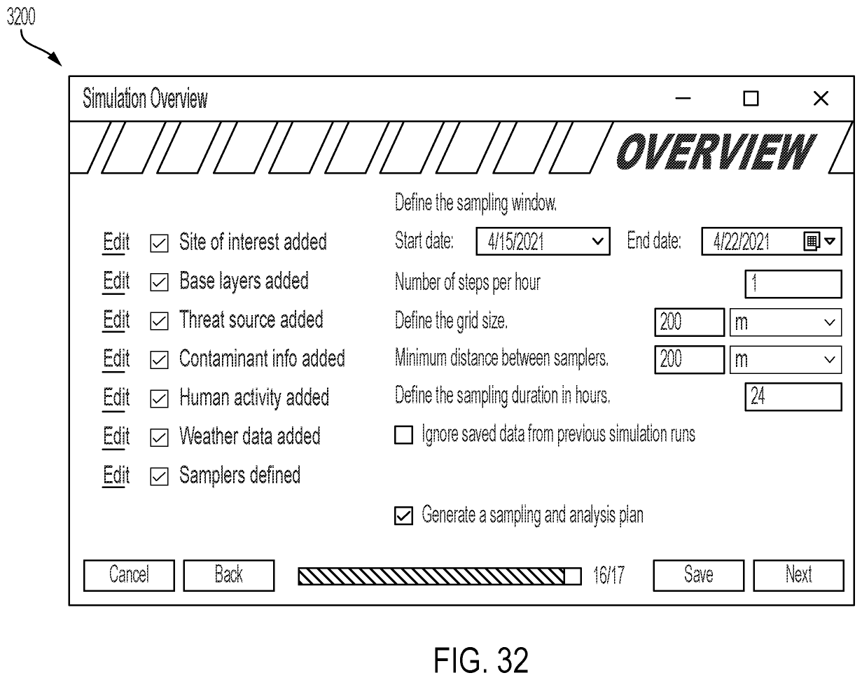

After obtaining the scenario data, the analysis compute device 200 in the illustrative embodiment, obtains simulation data indicative of one or more parameters under which to simulate emission of the chemical(s) at the site, in block 358. In doing so, the analysis compute device 200 may obtain data indicative of start and end dates for a sampling window, as indicated in block 360. The analysis compute device 200 may also obtain data indicative of a number of steps to simulate per hour, as indicated in block 362. The analysis compute device 200, in block 364, obtains data indicative of a size of each cell in a grid to be overlaid onto the site (e.g., thereby defining a resolution at which to execute the simulation). As indicated in block 366, the analysis compute device 200 illustratively obtains data indicative of a minimum distance between sampler devices. The minimum distance may not be less than the cell size from block 364. The analysis compute device 200 also obtains data indicative of a sampling duration as indicated in block 368. Additionally, the analysis compute device 200 may obtain data indicative of one or more user defined candidate sampler device locations (e.g., locations defined by the user, to be later compared against locations recommended by the analysis compute device 200), as indicated in block 370. Referring briefly to FIG. 32, the analysis compute device 200 may provide a user interface 3200 to enable the user to enter the simulation data described above. The user interface 3200 includes a progress bar indicating a progress of 16/17. After entering the information, the user selects the “next” button and, in response, the analysis compute device 200 displays a prompt for the user to specify where the SAP should be saved (e.g., folder and file name).

In block 372, the analysis compute device 200 simulates, as a function of (e.g., based on) the scenario data, emission of the chemical(s) at the site. As indicated in block 373, the analysis compute device 200 illustratively simulates transport and dispersion of a plume of the chemical across the site in space and time. The analysis compute device 200, in the illustrative embodiment, models (e.g., using one or more statistical models, algorithms, etc.) the shape, concentration, and propagation, of a plume of each chemical based on the properties of each chemical, weather phenomena typically present during the indicated time of year (based on the obtained meteorological data), and structures (e.g., buildings) that may affect wind directions and speeds local to the site and/or obstruct the path of the plume. As indicated in block 374, the analysis compute device 200 determines an exposure potential for each sector within the site. In doing so, and as indicated in block 376, the analysis compute device 200 determines the exposure potential as a function of (e.g., as the product of) population size, activity level of people in the population in each sector, and plume concentration in each sector. As an example, if one sector (7A) has a population of 50, an average activity level of 1, and a plume concentration of 0.000001 but another sector (7B), while having the same activity level, has a plume concentration of 10 and a population of 1, then the formula would calculate the first sector's exposure potential as 50×1×0.000001=0.000050 an the exposure potential of the second sector (7B) as 10. Accordingly, the algorithm would place more sampler devices in the second sector (7B) than the first sector (7A), provided that second sector (7B) was not designated by the user as off limits.

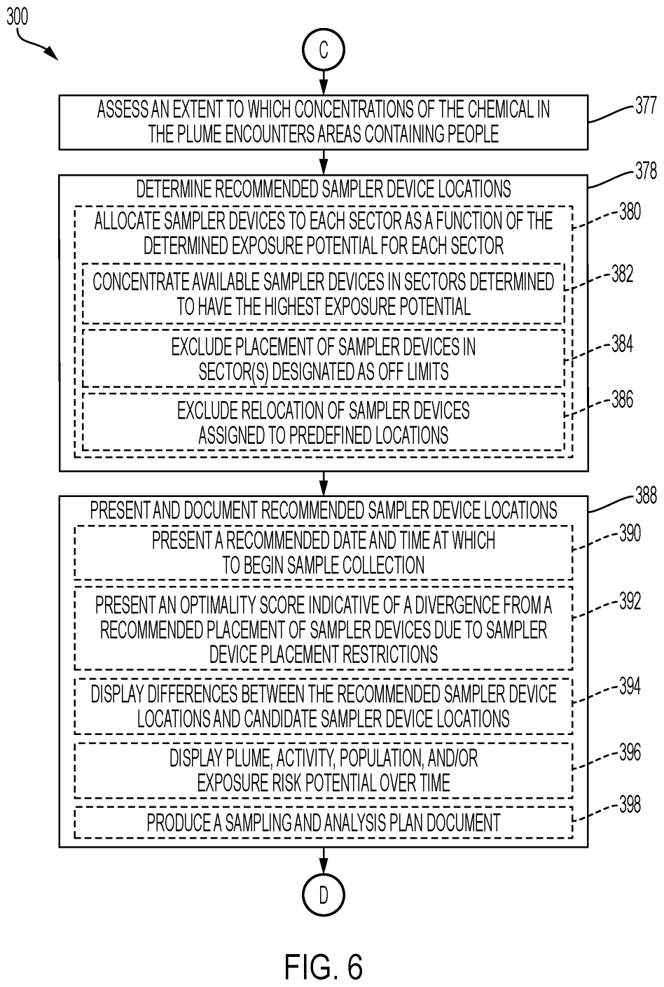

Referring now to FIG. 6, the analysis compute device 200 may assess an extent to which concentrations of the chemical in the airborne plume encounter areas containing people, as indicated in block 377. The compute analysis compute device 200 may perform the assessment based on (e.g., as a function of) time of day, projected human activity, and movement across the site. Additionally, the analysis compute device 200 determines (e.g., based on the simulation from block 372 and, in at least some embodiments, the assessment from block 373) recommended sampler device locations (e.g., to obtain a satisfactory quantity and quality of samples to determine the health hazards posed to the population at the site), as indicated in block 378. In doing so, and as indicated in block 380, the analysis compute device 200 allocates sampler devices to each sector as a function of the determined exposure potential for each sector (e.g., the exposure potentials determined in block 374). To increase the likelihood of obtaining a satisfactory set of samples, the analysis compute device 200 concentrates the placement of the available sampler devices in sector(s) determined (e.g., by the analysis compute device 200) to have the highest exposure potential, as indicated in block 382. Further, the illustrative analysis compute device 200 excludes placement of sampler devices from sector(s) designated as off limits (e.g., in block 328 of FIG. 3), as indicated in block 384. If applicable, in block 386, the analysis compute device 200 also excludes relocation of any sampler devices that were assigned to predefined locations in block 346 of FIG. 4.

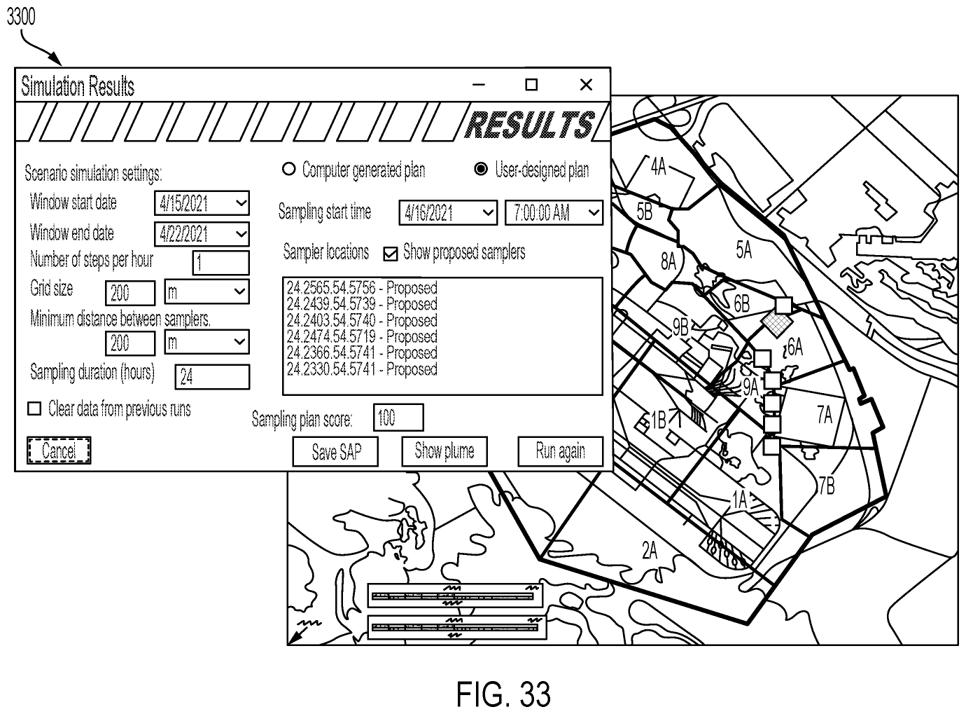

After determining the recommended sampler device locations, the analysis compute device 200 presents, and in the illustrative embodiment, documents, the recommended sampler device locations, in block 388. As indicated in block 390, the analysis compute device 200 may present a recommended date and time at which to begin sample collection, as indicated in block 390. The analysis compute device 200 may present an optimality score indicative of a divergence from a recommended placement of sampler devices due to sampler device placement restrictions (e.g., off limits sectors, unmodifiable locations assigned to certain sampler devices, etc.), as indicated in block 392. Referring briefly to FIG. 33, an illustrative embodiment of a user interface 3300 presented by the analysis compute device 200 for displaying the results of the simulation is shown. The proposed sampler device locations are overlaid onto an image of the site as a set of squares (e.g., yellow squares). The latitude and longitude coordinates for each sampler device are provided in a list. In the user interface 3300, the input conditions for the simulation dates, the available sampler devices, the grid size, and the sampler device distances are also shown. Further, the optimality score (e.g., sampling plan score) is also displayed. If no restrictions on the placement of sampler devices (e.g., off limits sector(s), unmodifiable locations for one or more sampler devices, etc.) were input by the user, then the optimality score is 100. Otherwise, if the placement of the sampler devices is hindered by one or more restrictions, the optimality score is less than 100.

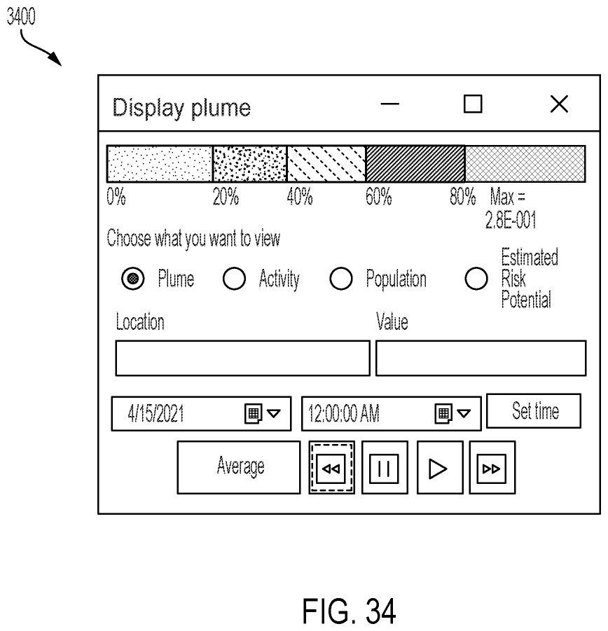

As indicated in block 394, the analysis compute device 200 may display differences between the recommended sampler device locations and candidate sampler device locations (e.g., showing the recommended locations in one color and the candidate locations in a different color). Through one or more user interfaces, the analysis compute device 200 may display the plume, activity, population, and/or exposure risk potential over time (e.g., as an animation), as indicated in block 396. Referring now to FIG. 34, the analysis compute device 200 may present a user interface 3400 for displaying a user-selected one of four parameters (plume, activity, population, or estimated risk potential) whose values can be presented graphically on the image of the site.

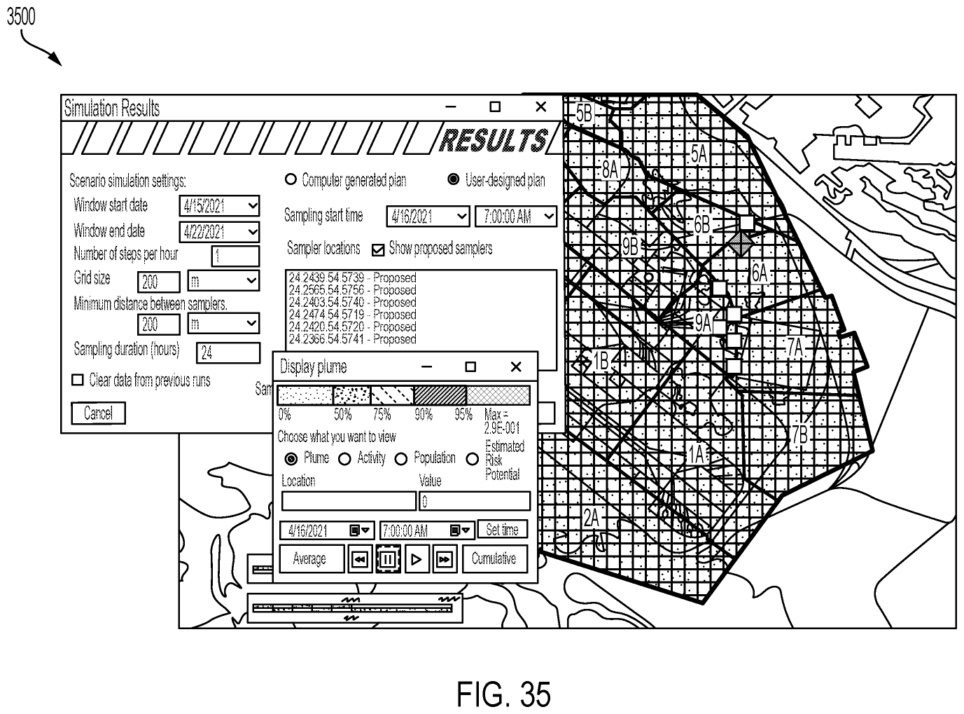

The illustrative user interface 3400 includes an “average” button. If the user selects the “average” button, the analysis compute device 200 displays the average of the plume, activity, population, exposure risk potential over the recommended sampling period (e.g., over a 24 hours sampling duration starting at 0700 on 4/16/2021). The analysis compute device 200 calculates the average in the same way for each of the four parameters (plume, activity, population, estimated risk potential). In the illustrative embodiment, the user interface 3400 also provides user interface elements to enable the user to enter a starting date and time and view the changes in the selected parameter (plume, activity, population, or estimated risk potential) as an animation beginning at the defined starting date and time. Additionally, the user interface 3400 also includes buttons for play (right arrowhead), pause (two vertical lines), reverse (two left-facing arrowheads) and forward (two right-facing arrowheads). These buttons allow the user to view the values over consecutive points in time within the sampling window, to pause the display at a specific time, to rewind to an earlier date and time in the sampling window, and to forward to a later date and time. Referring to a user interface 3500 shown in FIG. 35, the user may select the “plume” radio button to observe the contaminant concentration plumes as a graphical overlay on the image of the site. A color coded scale shows various contaminant concentration percentages of the absolute maximum of the plume at a given grid point. The user, in an illustrative example, enters the date and time for the start of the sampling event as Apr. 16, 2021 at 0700. The plume concentration across the site in this example is 0-50% of the calculated maximum value. If the user selects the “average” button, the analysis compute device 200 displays the plume concentration over the site as averaged over the selected sampling window. Over the course of the optimum sampling day, the plume concentration levels are determined as the maximum for starting the sampling event on the indicated date and time because the data are expressed as maximum concentrations over the sampling window event. While other dates may have higher concentrations, for this sampling window, the specified date and time is determined, by the analysis compute device 200, to be the optimum time for sample collection.

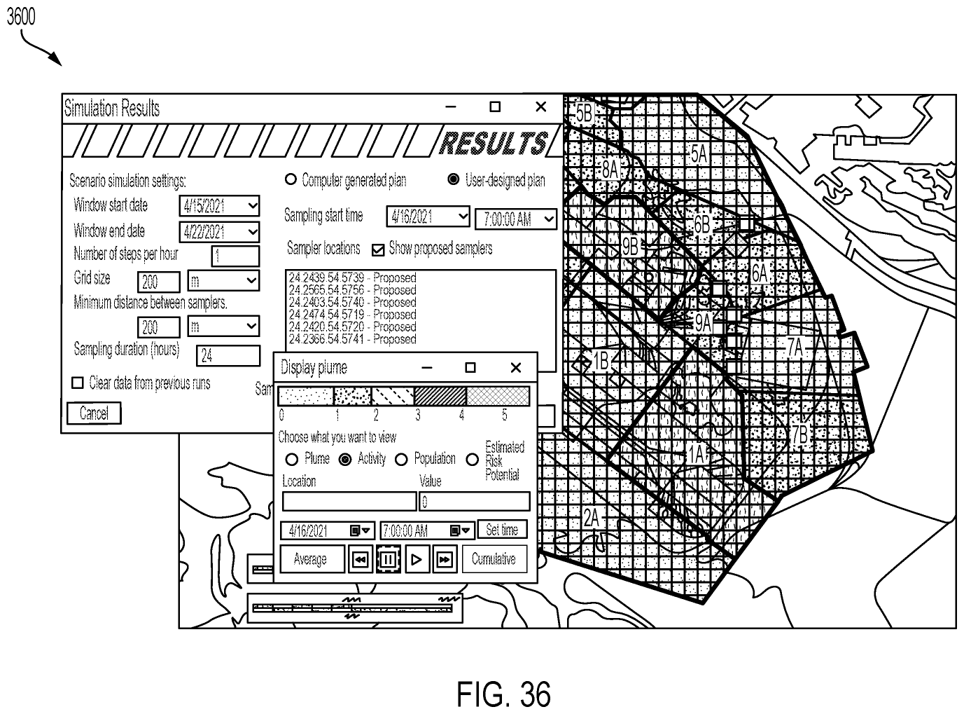

Referring now to FIG. 36, in a user interface 3600 in which the “activity” radio button has been selected by the user, the analysis compute device 200 displays human activity levels in the sector on a 0 to 5 ordinal category scale defined earlier (e.g., as read from the human activity data file). A color-coded scale displays the 0 to 5 ordinal category scale. The user sets the date and time within the user interface 3500 to the optimum start for the sampling event. In the example, on Apr. 16, 2021 at 0700, sector 9B is at activity level 4. This sector is classified according to the affected population at risk, as shown by a corresponding dot, which may be coded with a corresponding color (e.g., green).

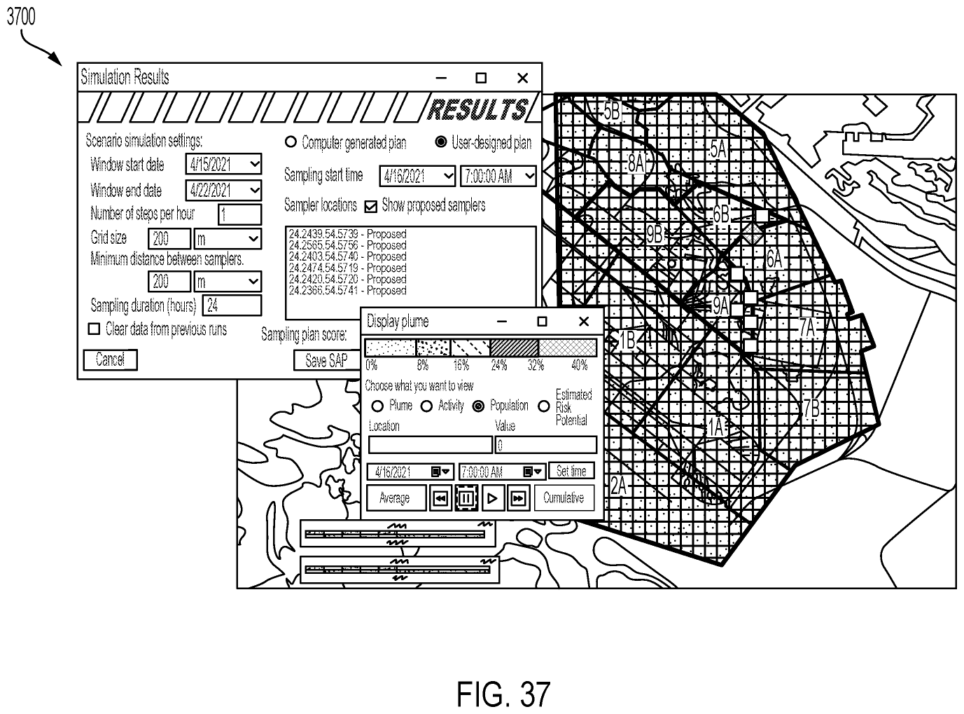

Referring now to FIG. 37, in a user interface 3700, the user has selected the “population” radio button to display the percentages of the total population within each plume at a given point in time (e.g., as taken from the human activity data file). A color-coded scale in the user interface 3700 displays a 0-100% range which the population percentages could hold. The user sets the date and time within the user interface 3700 to the optimum start for the sampling event. In the example, on Apr. 16, 2021 at 0700, sectors 9A and 9B and 6B contain the highest percentages of the total population in the area of interest. In the example, a sampler device was placed in sector 6B in part due to the size of the population in that sector.

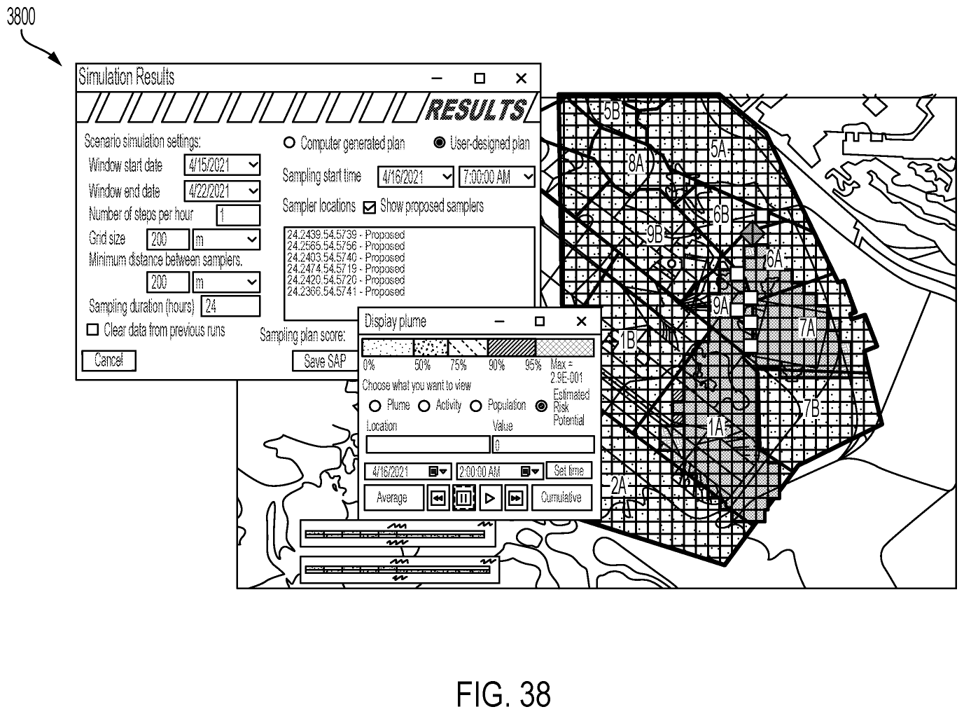

In FIG. 38, in a user interface 3800, an “estimated risk potential” radio button is selected to cause the analysis compute device 200 to display the value of a metric that combines the plume, activity, and population information. The estimated risk potential is a measure of the influence of the above parameters on the sampler device selection over the 24-hour window selected within the sampling event timeframe. A color-coded scale indicates the range of the estimated risk potential. In the example, the largest values of estimated risk potential during the 24-hour sampling window occur at Apr. 16, 2021 at 1400. Within any of the four options, the user may select a point on an image of the site to mark a specific location to display the value of the selected parameter within location and value fields in the user interface 3800. For the estimated risk potential plume, the example demonstrates how a point is marked within sector 9B at 1400 on Apr. 16, 2021 and how its geographic coordinates and estimated risk potential value are displayed within the location and value fields, respectively, in the user interface 3800.

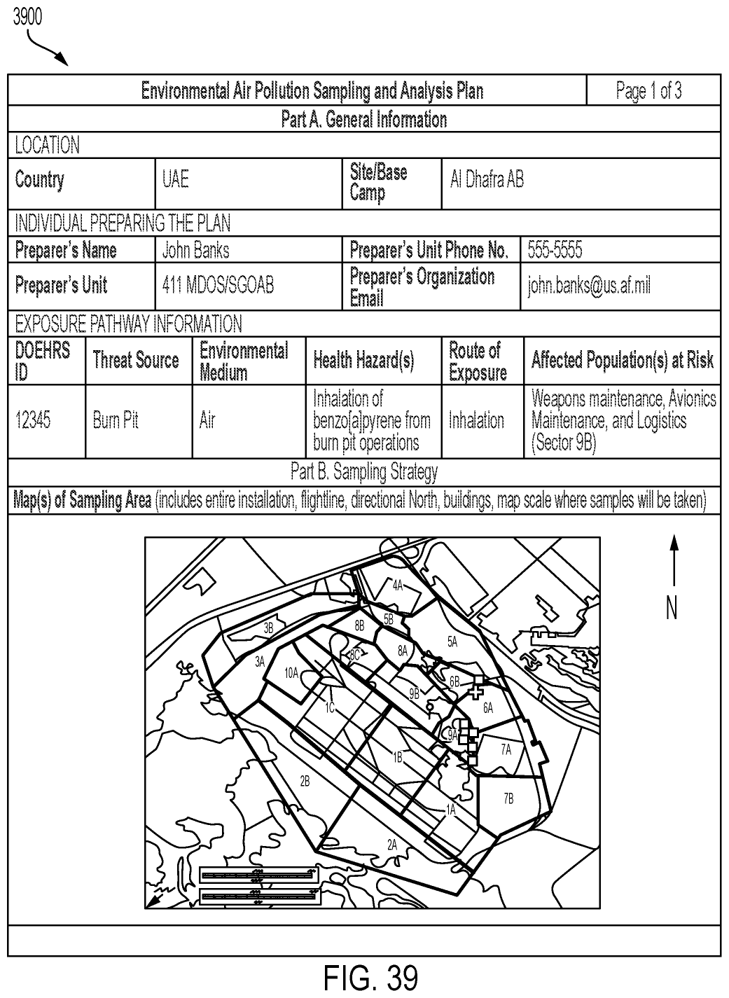

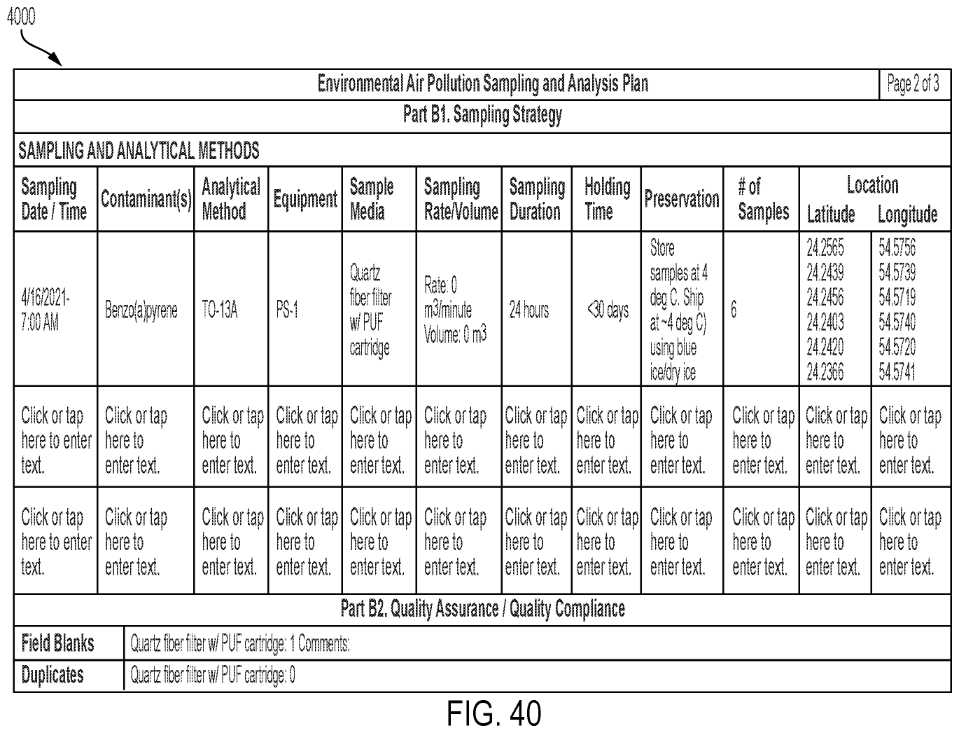

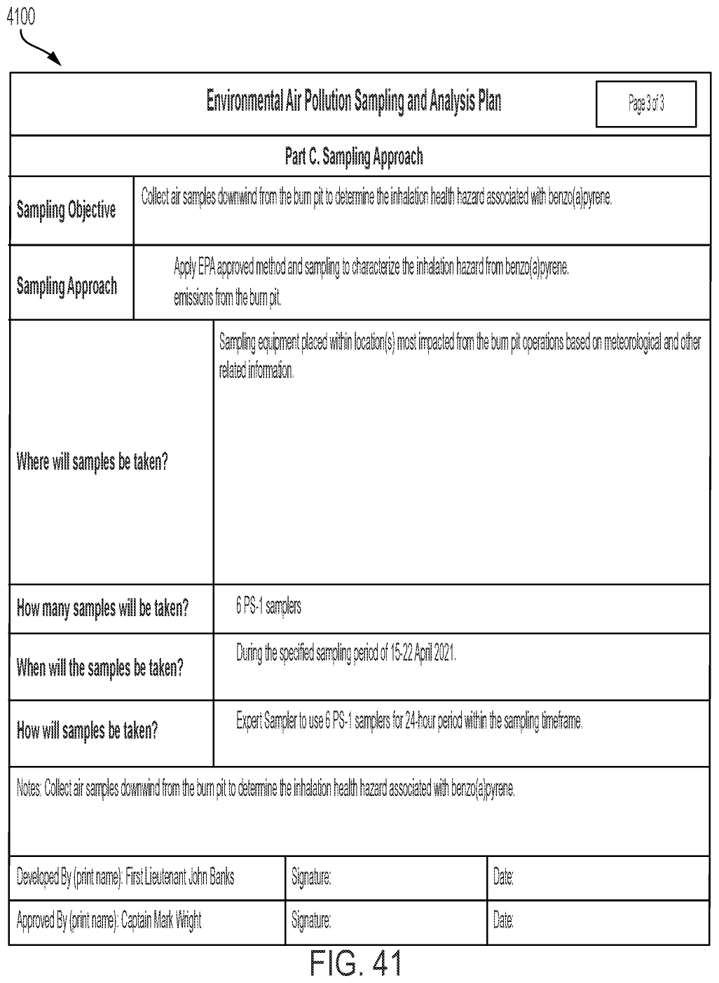

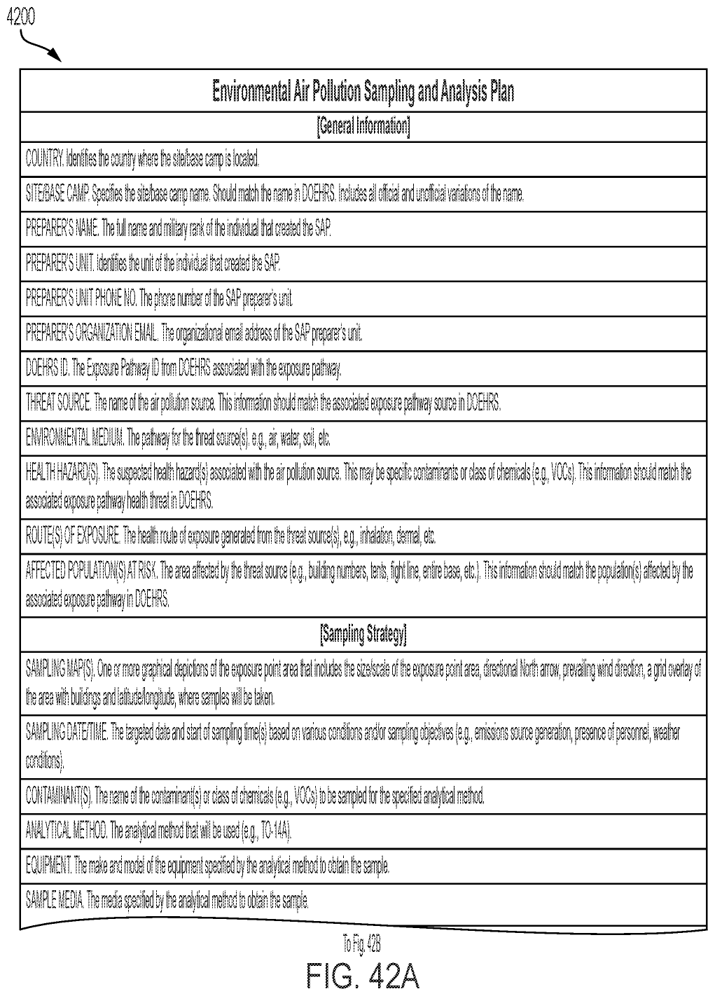

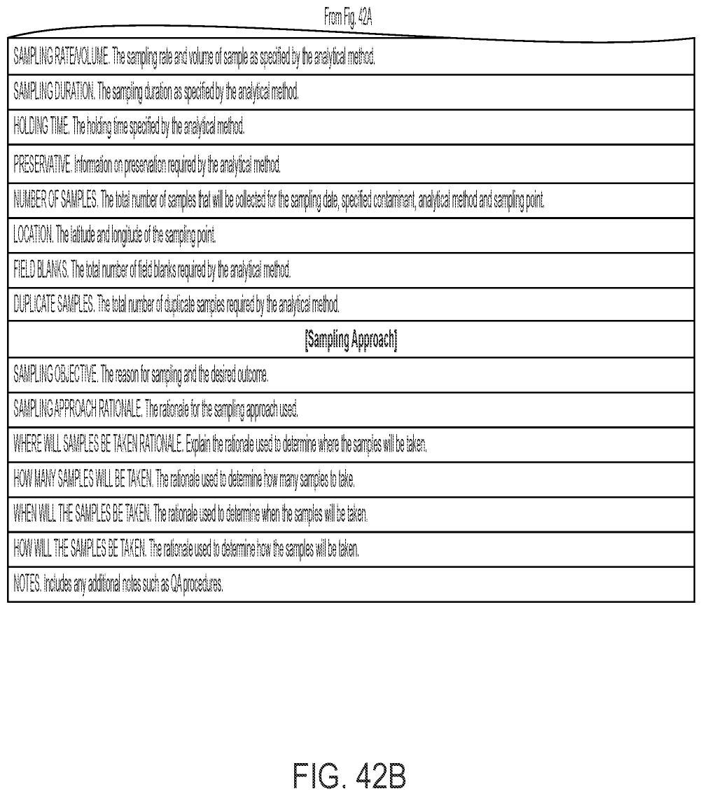

Referring back to FIG. 6, in the illustrative embodiment, the analysis compute device 200 produces a sampling and analysis plan document, as indicated in block 398. FIGS. 39, 40, and 41 illustrate corresponding sections 3900, 4000, 4100 of an example sampling and analysis plan document that may be produced by the analysis compute device 200. Additionally, FIGS. 42A and 42B depict a chart indicative of the type of information provided in each text block of the sections 3900, 4000, 4100 of the sampling and analysis plan document. Referring back to FIG. 6, after producing the sampling and analysis plan document, the method 300 loops back to block 302 of FIG. 3 to determine whether to produce another sampling and analysis plan.

While certain illustrative embodiments have been described in detail in the drawings and the foregoing description, such an illustration and description is to be considered as exemplary and not restrictive in character, it being understood that only illustrative embodiments have been shown and described and that all changes and modifications that come within the spirit of the disclosure are desired to be protected. There exist a plurality of advantages of the present disclosure arising from the various features of the apparatus, systems, and methods described herein. It will be noted that alternative embodiments of the apparatus, systems, and methods of the present disclosure may not include all of the features described, yet still benefit from at least some of the advantages of such features. Those of ordinary skill in the art may readily devise their own implementations of the apparatus, systems, and methods that incorporate one or more of the features of the present disclosure.

1. A compute device for facilitating an analysis of airborne chemical hazards comprising:
circuitry configured to:
obtain scenario data indicative of emission of an airborne chemical at a site with a human population, wherein the scenario data includes meteorological data for the site and a location of an emission source for the airborne chemical;
simulate, as a function of the scenario data, emission of the chemical at the site and transport and dispersion of a plume of the chemical across the site in space and time;
assess an extent to which concentrations of the chemical in the airborne plume encounter areas containing people, as a function of time of day and projected human activity and movement across the site;
determine, based on the simulation and assessment, recommended sampler device locations to obtain a target quality and target quantity of samples of the chemical for use in a sampling and analysis plan to determine an effect of the chemical on the human population at the site; and
present the recommended sampler device locations.

2. The compute device of claim 1, wherein to obtain scenario data comprises to obtain sector data indicative of locations and shapes of sectors within the site, including population data indicative of the human population in each sector and activity data indicative of a level of human activity per hour in each sector.

3. The compute device of claim 2, wherein to obtain the sector data comprises to obtain data indicative of at least one sector in which sampler device placement is prohibited.

4. The compute device of claim 1, wherein to obtain the scenario data comprises to obtain emission source data indicative of properties of the emission source, including the size of the emission source and temperature over time for the emission source.

5. The compute device of claim 1, wherein to obtain the scenario data comprises to obtain data indicative of a location of the site and a perimeter of the site.

6. The compute device of claim 1, wherein to obtain the scenario data comprises to obtain data indicative of perimeters of one or more buildings at the site.

7. The compute device of claim 1, wherein to obtain the scenario data comprises to obtain data indicative of an identity and one or more properties of the chemical.

8. The compute device of claim 1, wherein to obtain the scenario data comprises to obtain data indicative of a profile of the chemical.

9. The compute device of claim 1, wherein to obtain the scenario data comprises to obtain data indicative of a sector of heightened interest to be prioritized for sampler device placement.

10. The compute device of claim 1, wherein to obtain the scenario data comprises to obtain data indicative of air sampling parameters for the chemical.

11. The compute device of claim 1, wherein to obtain the scenario data comprises to obtain data indicative of an analytical method, equipment, sample media, sampling duration, sample rate, sampling volume, and a quantity of sampler devices.

12. The compute device of claim 1, wherein to obtain the scenario data comprises to obtain data indicative of a predefined sampler device location that cannot be modified.

13. The compute device of claim 1, wherein to obtain the scenario data comprises to obtain data indicative of a field blank or duplicate samples.

14. The compute device of claim 1, wherein to obtain the meteorological data comprises to obtain data indicative of historical weather data for the site for multiple years and data indicative of hourly air temperature, wind speed, wind direction, and atmospheric stability measures.

15. The compute device of claim 1, wherein the circuitry is further configured to obtain simulation data indicative of parameters under which to simulate emission of the chemical at the site, wherein the simulation data includes data indicative of start and end dates for a sampling window, data indicative of a number of steps per hour, data indicative of a size of each cell in a grid to be overlaid onto the site, data indicative of a minimum distance between sampler devices, and data indicative of a sampling duration.

16. The compute device of claim 1, wherein the circuitry is further configured to:
obtain data indicative of user defined candidate sampler device locations; and
display differences between the recommended sampler devices locations and the candidate sampler device locations.

17. The compute device of claim 1, wherein the circuitry is further configured to present a recommended date and time at which to begin sample collection.

18. The compute device of claim 1, wherein the circuitry is further configured to present an optimality score indicative of a divergence from recommended sampler device locations due to sampler device placement restrictions.

19. The compute device of claim 1, wherein the circuitry is further configured to display plume, activity, population, or exposure risk potential over time.

20. The compute device of claim 1, wherein to present the recommended sampler device locations comprises to produce a sampling and analysis plan document.
